(19) United States
(12) Patent Application Publication
(10) Pub. No.: US 2007/0152209 A1
(43) Pub. Date: Jul. 5, 2007

(54) Devices using polymers based on 3,6- and 2,7-conjugated poly(phenanthrene)

(76) Inventor: Frank P. Uckert, Buellton, CA (US)

Correspondence Address: E I DU PONT DE NEMOURS AND COMPANY;LEGAL PATENT RECORDS CENTER, BARLEY MILL PLAZA 25/1128, 4417 LANCASTER PIKE, WILMINGTON, DE, 19805, US

(21) Appl. No.: 11/642,378

(22) Filed: Dec. 19, 2006

Related U.S. Application Data
(60) Provisional application No. 60/751,697, filed on Dec. 19, 2005.

(51) Int. Cl. H01L 51/00; H01L 51/54

(52) U.S. Cl. 257/40; 257/E51.028; 428/690; 428/917; 313/504; 313/506

(57) ABSTRACT

A device having at least one layer including poly(p-phenylene)s based on 3,6-conjugated and 2,7-conjugated phenanthrene moietie having been synthesized by polycondensation using Ni(O)-mediated Yamamoto-type cross coupling are described as the charge transport layer or as the host for a dopant.

### CROSS REFERENCE TO RELATED APPLICATION

This application claims priority from U.S. Provisional Application No. 60/751,697, filed Dec. 19, 2005, which is incorporated by reference herein in its entirety.

### BACKGROUND INFORMATION

1. Field of the Disclosure

This disclosure relates in general to poly(p-phenylene)s, and in particular to poly(phenanthrene)s.

2. Description of the Related Art

Among the conjugated polymers for use in light-emitting diodes (LEDs), phenylene-based polymers constitute an important class in that they emit in the blue range of the spectrum and at the same time can act as hosts for downhill energy transfer to generate green and red emitters. Also, these materials may be suitable hosts for up-conversion photoluminescence which is significant in the development of blue lasers. The poly(p-phenylene) (PPP) backbone has a 23° twist between consecutive aryl units due to ortho-hydrogen interactions and the introduction of solubilizing side chains leads to steric interactions, which cause a marked increase in the phenylene-phenylene torsion angle up to over 60°, with a concurrent loss of π-overlap and a marked blue-shift in the emission wavelength. To overcome this shortcoming, there has recently been a large amount of synthetic effort to prepare and exploit more planarized PPP systems, since the first fully planarized ladder-PPP was reported by Scherf and Müllen. The methine bridges in PPP based polymers (see below) such as poly(dialkylfluorene)s (PFs, PI), poly(tetraalkylindenofluorene)s (PIFs, PII), and ladder-type polyphenylenes (LPPPs, PIII) develop an unwanted bathochromically shifted blue-green emission due to the formation of ketone defects at the C-9 position. Also, vinylene-bridged ladder-type PPP polymers (PIV) possess a non-planar backbone geometry with a predicted distortion angle of about 20° between adjacent phenylene rings. The so-called angular poly(acene)s, PV, have also been synthesized and this class of conjugated materials display a drastically reduced quantum efficiency for photo- and electroluminescence and greenish-blue emission due to long extended conjugation (λₑₘ=478-516 nm) in comparison with PPPs with methine-bridges. The polymers cited above have the following structures:

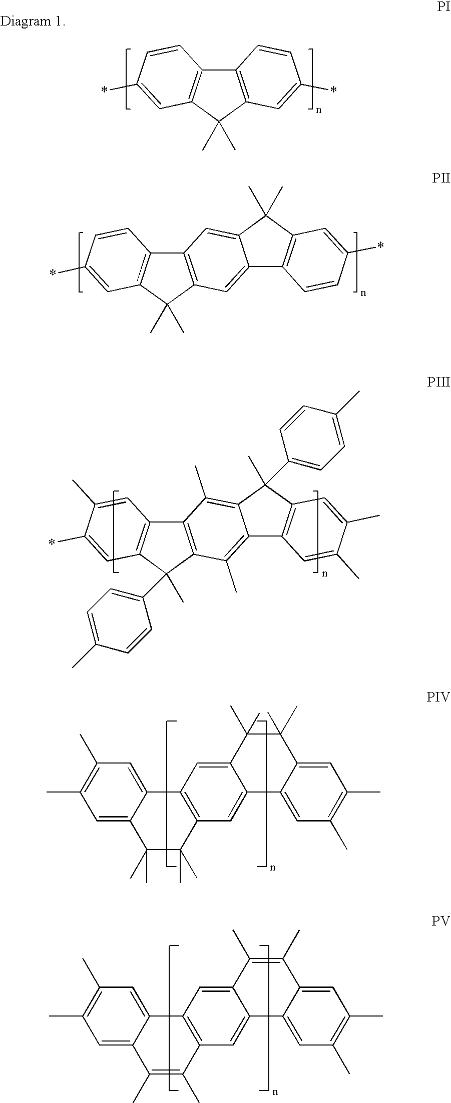

### SUMMARY

Provided are polymers having Formula I or Formula II 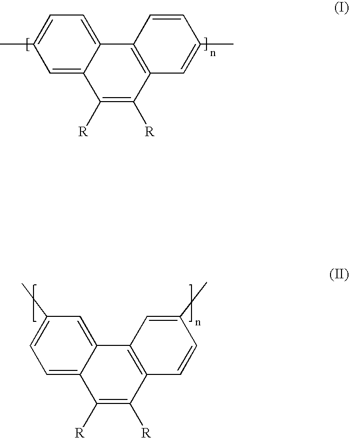
wherein:
R is the same or different at each occurrence and is: H, alkyl, or aryl, and
n is an integer greater than 5.

The polymers above may be used in organic electronic devices in the charge transport layer, including the hole and electron transport layer, and further may act as a host for a dopant (e.g., small organic photoactive molecules and organometallic compounds).

In addition, electronic devices comprising at least one of the foregoing polymers are also provided.

### BRIEF DESCRIPTION OF THE FIGURES

FIG. 1 shows GPC curves (standard PPP) of polymer 3,6-PAP via Yamamoto (dashed line) and polymer 3,6-LPAP via Suzuki polymerization (solid line).

FIG. 2 MALDI-TOF mass spectrum of the oligomeric fraction of the polymer 3,6-PAP.

FIG. 3 depicts cyclic voltammograms of the polymer films coated on platinum electrodes measured in acetonitrile containing 0.1 M Bu₄NClO₄ solution at a scan rate of 100 mV/s at room temperature.

FIG. 4 presents UV-vis absorption spectra of 2,7-conjugated polymers and their model trimer in THF solution.

FIG. 5 shows PL emission spectra of 2,7-conjugated polymers and their model trimer.

FIG. 6 depicts UV-vis absorption spectra of 3,6-conjugated polymers and their model trimer and macrocyclic trimer in THF solution.

FIG. 7 shows UV-vis absorption spectra of 3,6-conjugated polymers and their model trimer and macrocyclic trimer in THF solution.

FIG. 8 is a schematic diagram of an exemplary electronic device, an organic light-emitting diode (OLED) display that includes at least two organic active layers positioned between two electrical contact layers.

### DETAILED DESCRIPTION

Described herein are devices having at least one layer including at least one of the above described polymers, which have been created by the synthesis and characterization of derivatives based on 2,7- or 3,6-conjugated polyphenanthrenes. Phenanthrenes can be polymerized using either 2,7-linkages to generate a linear rigid, rod-like polymer or along 3,6-linkages to create a polymer where the bond angle between successive phenanthrene units is much smaller than 180°. In comparison with ladder-type PPP with methine bridges, phenanthrene polymers offer several advantages: (i) once the PPP backbone is intact, the attachment of alkyl or aryl solubilizing groups at the 9,10-positions can lead to soluble polymers without disturbing conjugation along the chain; (ii) a double-bonded bridging unit between phenylene moieties keep the consecutive aryl units planar while extending π-conjugation through the PPP backbone thereby lowering the band gap; (iii) the susceptibility of the methine-bridges towards oxidation leading to the formation of keto defects is minimized since they are less easily oxidized; and (iv) the stilbene-type double bonds can stabilize both electrons and holes and thereby improve charge injection and transport.

We disclose herein the synthesis of novel 2,7- and 3,6-linked soluble polyphenanthrenes as well as results on their electroluminescence behavior. Also, the synthesis of 3,6- and 2,7-linked trimers as model compounds is described and comparison is made between their properties and the corresponding polymers. Without limiting the invention, it is believed that while the Yamamoto-type polymerization along 3,6-linkages predominantly leads to the formation of a macrocyclic trimer, using a Suzuki-Miyaura type polycondensation, it is possible to synthesize polyphenanthrenes with improved molecular weights and avoid the formation of cycles.

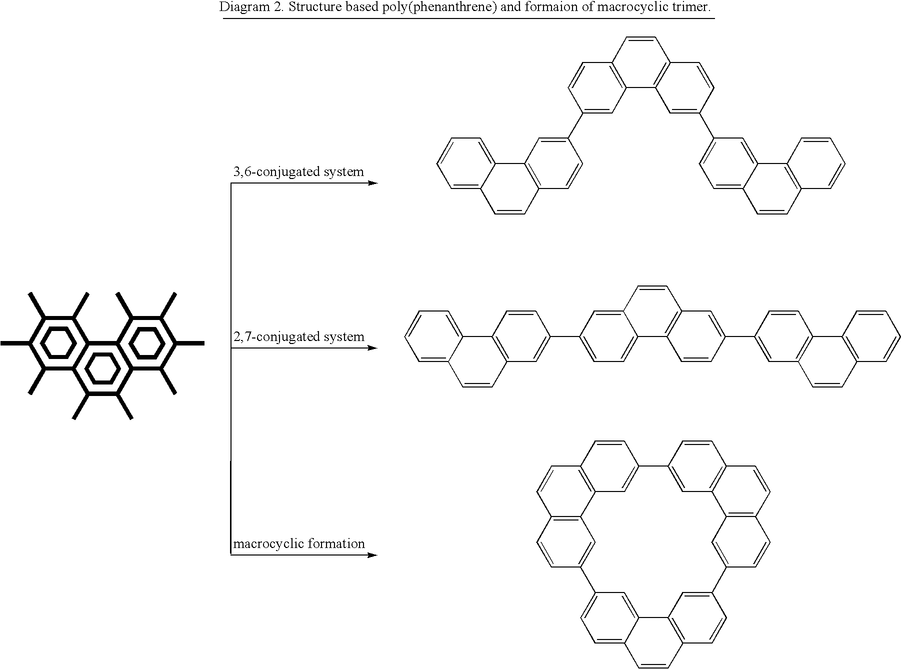

### SYNTHESIS

### EXAMPLE 1

### Synthetic Route to 2,7-conjugated poly(dialkylphenanthrene)

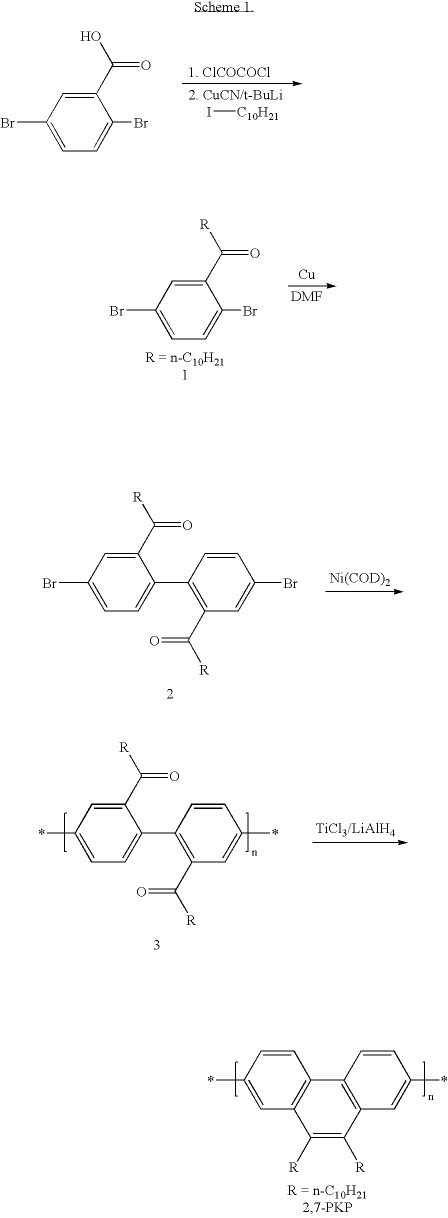

The synthetic approach to poly(2,7-dialkylphenanthrene) is depicted in Scheme 3, above. 2,5-dibromobenzoic acid was first converted to 2,5-dibromobenzoyl chloride by treatment with oxalyl chloride which was then coupled with decyl lithium in presence of CuCN to generate the decyl ketone 1 in 70% isolated yield.⁶ Ullmann coupling of 1 in the presence of copper powder gave the symmetrical biphenyl compound 2 (43%). The target polymer 2,7-PKP was synthesized by initial polymerization of 2 and subsequent cyclisation by McMurry coupling. The biphenyl polymer 3 was synthesized by a nickel(0)-mediated Yamamoto-type polymerization and was readily soluble in organic solvents like THF, toluene, chloroform, and dichloromethane. The polymer 2,7-PKP after cyclisation showed a Mₙ of 4.68×10⁴ g/mol and M_{w} of 9.78×10⁴ g/mol by Gel-permeation chromatography (GPC) analysis against PPP standards. All materials were characterized by a combination of FTIR, ¹H and ¹³C NMR spectroscopy. In the IR spectra, the peak about 1690 cm⁻¹ due to the carbonyl group in the polymer 3 disappeared upon ring closure in the polymer 2,7-PKP and its ¹³C NMR spectrum showed no carbonyl signals (at 196 ppm for 3), indicating a complete conversion. However, this polymer had only limited solubility in common organic solvents (THF, toluene, dichloromethane etc.) and showed greenish-blue emission in solution. The low solubility can be attributed to better stacking upon planarization.

### EXAMPLE 2

### Synthetic Route to 3,6-conjugated poly(dialkylphenanthrene)

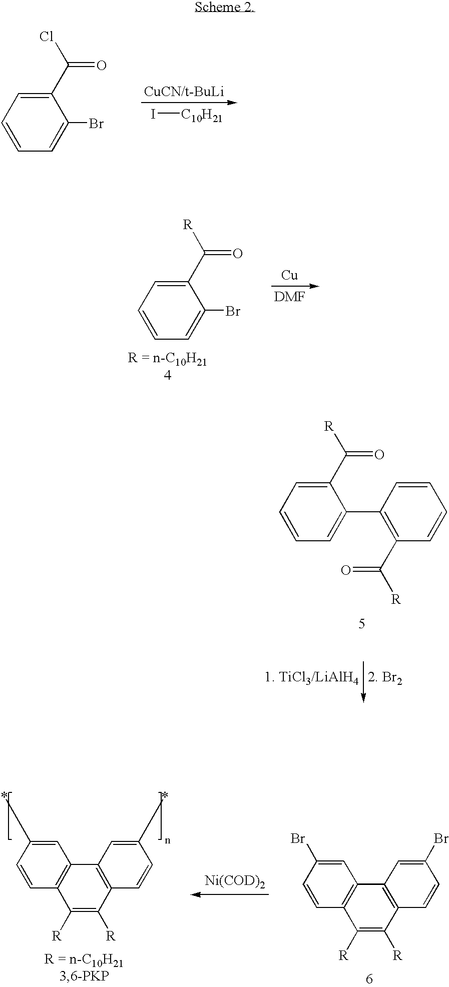

The analogous 3,6-linked polymer was synthesized starting from 2-bromobenzoyl chloride as shown in Scheme 4, below. The synthetic sequences are similar to the one described in Example 1 (acylation, Ullmann, and McMurry) and the monomer 6 was isolated in an overall yield of 17%. The polymer 3,6-PKP was synthesized by a Yamamoto-type polymerization, which was readily soluble in organic solvents. GPC analysis of this polymer exhibited a Mₙ value of 3.2×10³ g/mol and M_{w} of 5.1×10³ g/mol (THF, PPP standards). Although attempts were made to improve the molecular weight by varying the concentration as well as the order of addition of the nickel reagent into the monomer solution³⁶, the polymerization always resulted in low molecular weight (Mₙ=3000-4000 D) materials.

### EXAMPLES 3-4

### Synthetic Route to 3,6-conjugated poly(diarylphenanthrene)

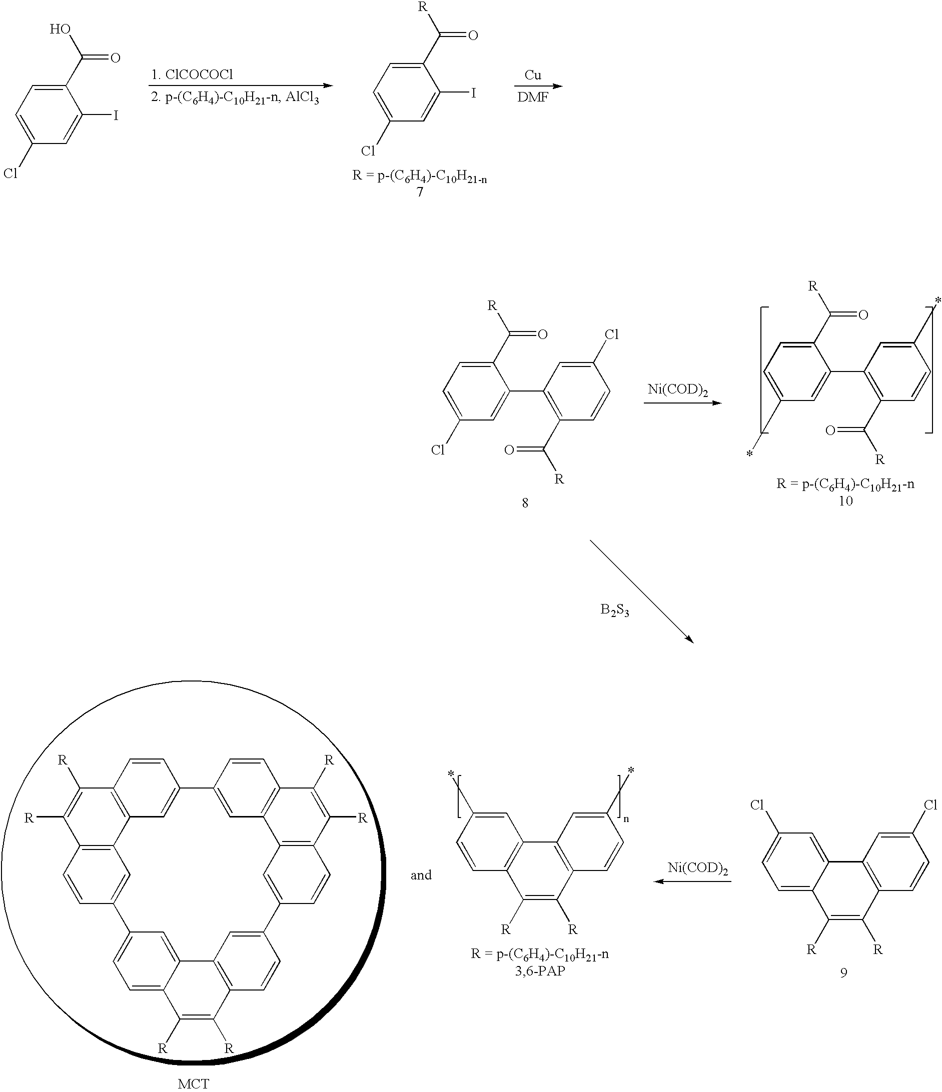

Also synthesized were the corresponding 9,10-diaryl substituted polymers to compare their solubility as well as long term stability in devices. Scheme 3 illustrates the synthetic approach towards 3,6-linked polymers. The ketone compound 7 was prepared by AlCl₃-promoted Friedel-Crafts acylation of decyl benzene with 4-chloro-2-iodo-benzoyl chloride in 91% overall yield. Ullmann-type coupling reaction followed by cyclisation of 8 using tricyclohexyltin sulfide and BCl₃ generated 9 in an overall yield of 55%. Polymerization of 9 gave only low molecular weight (Mₙ=4.25×10³ g/mol and M_{w}=7.55×10³ g/mol, THF, PPP standards) polymer. In an alternate approach, initial polymerization of the diketone precursor 8 was carried out to improve the molecular weight but the resulting polymer 10 also showed low molecular weight (Mₙ=2.14×10³ g/mol, THF, PPP standards).

Without limiting the invention and not wishing to be bound by theory, it was reasoned that the di-nickel-substituted complex formed by oxidative addition to 8 has less stability leading to chain termination or hydrolysis on one or both sides whereas the low molecular weight from the polymerization of 3,6-dichlorophenanthrene itself can be attributed to possible formation of macrocycles during polymerization. We observed that the synthesis of arylboronic ester compound from (2-bromo-phenyl)-(4-decyl-phenyl)-ketone or (2-iodo-phenyl)-(4-decyl-phenyl)-ketone with bis(pinacolato)diboron under palladium catalysts gave a large number of debrominated compounds (ca. 35-45%) supports this hypothesis. Polyphenanthrenes linked at the 2,7-position form straight, linear macromolecules whereas 3,6-polyphenathrenes should have a more bent helical structure. This bent structure can lead to the formation of macrocyles instead of linear polymers.

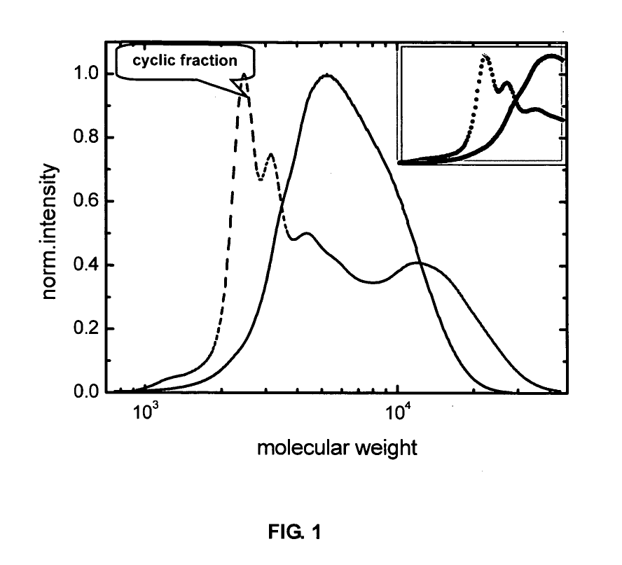

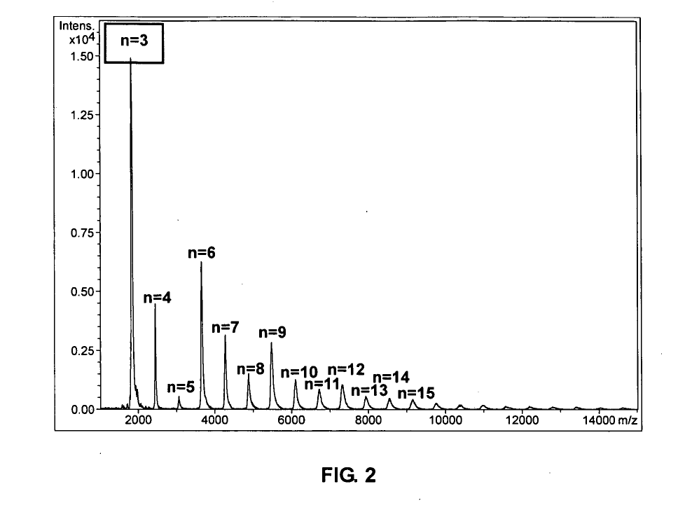

GPC analysis of polymer 3,6-PAP shows a large amount of low molecular fraction (ca.>2500 g/mol) as shown FIG. 1 and MALDI-TOF mass spectrometry turned out to be an ideal tool for the structure elucidation of the oligomeric fraction (FIG. 2). The MALDI spectrum of this polymer shows one significant strong intense peak at 1,827 Dalton and a number of small peaks up to 15,000 Dalton. The peak at 1,827 Dalton stems from the macrocyclic trimer. These results clearly indicate the formation of a macrocyclic trimer via Yamamoto polymerization and this material was isolated by preparative TLC. Furthermore, when the Yamamoto polymerization of 9 was carried out in very dilute solution, only oligomers were formed and the predominant product, the cyclic trimer MCT, was isolated by column chromatography. This material which shows strong blue emission in solution, was characterized by ¹H and ¹³C NMR and Field Desorption Mass Spectrometry (calculated m/z: 1826.8; found m/z: 1825.0 (M^{+*})). The thermal properties were determined by TGA and DSC measurements. MCT shows good thermal stability, with onset decomposition temperature (T_{d}, 5% weight loss) of 420-430° C. under nitrogen. Differential scanning calorimetry (DSC) traces revealed two endothermic phase transitions (higher order phase and plastic phase) at 51° C. and 148° C.

### EXAMPLE 4

Polymerization by Suzuki coupling of 3,6-conjugated phenanthrene was undertaken to improve the molecular weight because from mechanistic considerations, this avoids the formation of a macrocyclic trimer as shown in Scheme 4. 3,6-diboronic ester of phenanthrene 14 was prepared by a palladium-catalyzed coupling reaction of 9 with bis(pinacolato)diboron under Pd₂(dba)₃/PCy₃/KOAc and the 3,6-dibromide 13 was synthesized from 2-iodo-benzoyl chloride in an analogous approach as discussed earlier. The Suzuki coupling of 13 with 14 gave the linear polymer 3,6-LPAP with highly improved molecular weights (Mₙ=5.3×10³ g/mol and M_{w} of 6.8×10³ g/mol, PPP standards). This polymer has good solubility in common organic solvents and and is a blue-emitter.

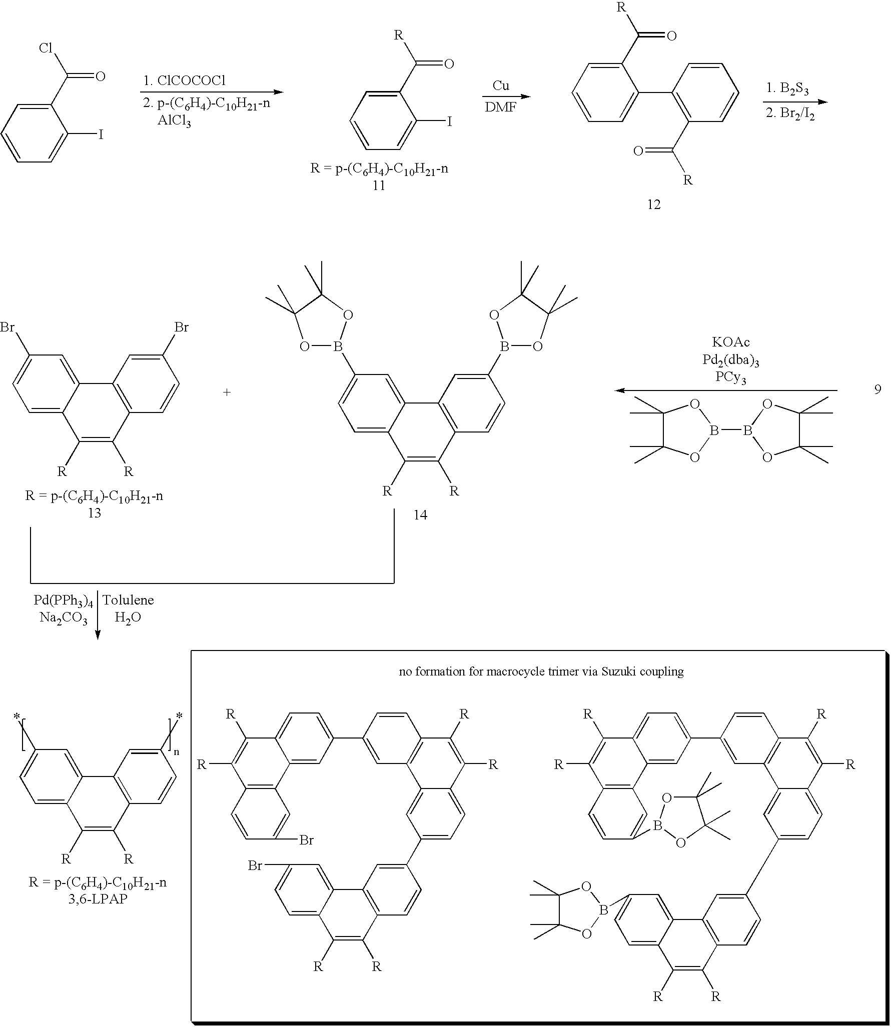

### EXAMPLE 5

Polymer 2,7-PAP was synthesized starting from 5-bromo-2-iodo-benzoic acid as depicted on Scheme 5, below, by similar procedures as those detailed above. The polymer 2,7-PAP is readily soluble in common solvents and shows a pure blue emission (Mₙ=1.1×10⁴ g/mol and M_{w}=5.3×10⁴ g/mol, PPP standards). TGA thermograms of all the polymers exhibit good thermal stability up to 350° C. Weight loss (5%) starts at 380, 425, 445, and 430° C. for polymers 2,7-PKP, 2,7-PAP, 3,6-PKP, and 3,6-LPAP respectively. DSC analysis of the polymers showed neither a glass transition process (T_{g}) nor other thermal processes (such as liquid crystalline phase) from −50° C. to 200° C.

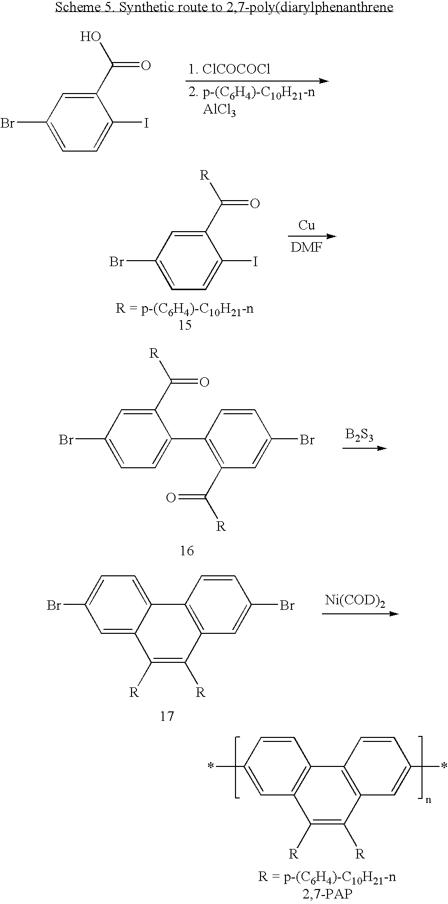

### EXAMPLE 6

### Synthesis of Model Trimers and Their Characterization

To more precisely assess the degree of extended conjugation between 3,6- and 2,7-conjugated polyphenanthrenes, 3,6- and 2,7-linked model trimers were prepared. The synthesis of the model compounds is shown in Schemes 6 and 7. The ketone compound 18 was coupled with boronic ester compound 19 (50%) by Suzuki reaction and subsequent cyclisation of the diketo compound gave 21 (89%). The mono chloride 21 was converted into the corresponding boronic ester 22 under Pd₂(dba)₃/KOAc with tricyclohexylphosphine as a ligand (72%). Suzuki coupling of this compound 22 with 17 gave 2,7-conjugated model trimer 2,7-MT (26%). Additionally, the synthesis towards 3,6-conjugated model trimer was carried out according to Scheme 7 and obtained the model trimer 3,6-MT (71%) via Suzuki coupling of this compound 23 with 14.

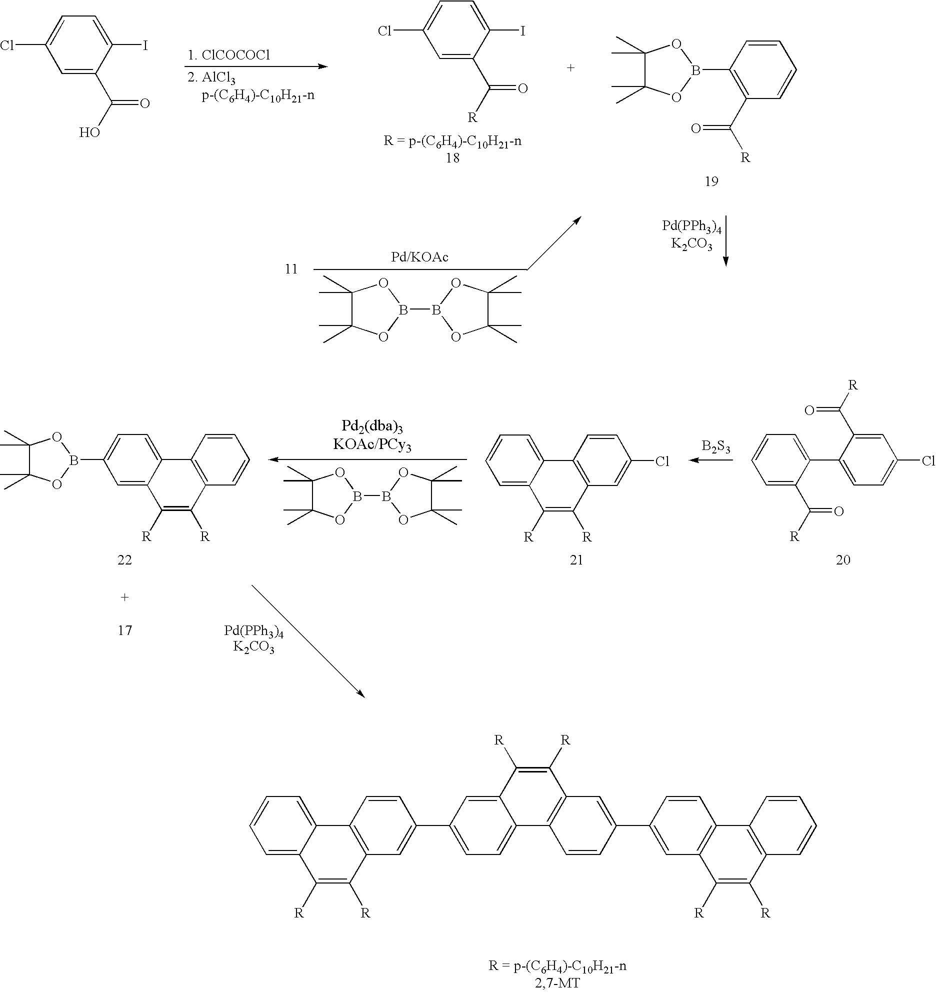

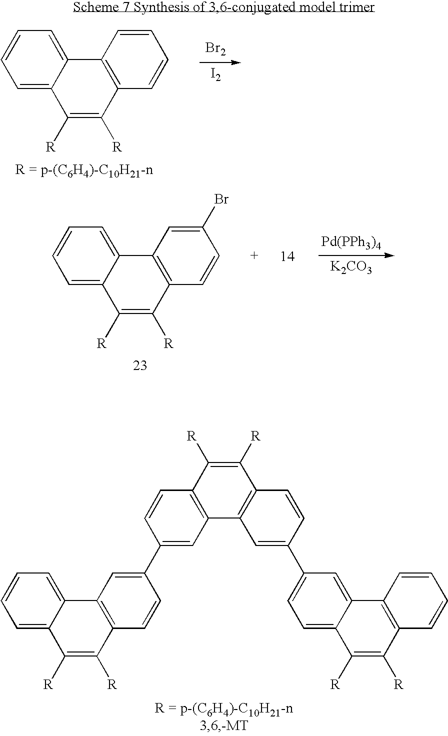

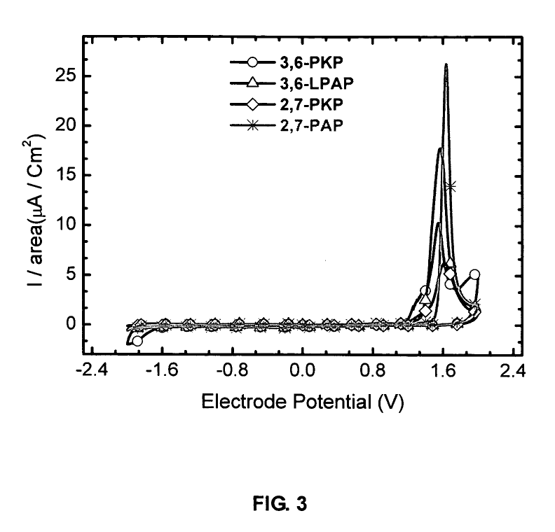

Electrochemical Properties. The electrochemical redox behavior of the polymers was investigated by cyclic voltammetry (CV) against Ag/Ag+, by the method of Janietz, et al., Appl. Phys. Lett., 1998, 73, 2453-2455. As shown in FIG. 3, all the polymers exhibit only p-doping (oxidation) peaks, and the CV data are listed in Table 1. All the polymers exhibit irreversible anodic peaks at 1.54 V vs Ag/Ag+ for 3,6-PKP, 1.57 V for 3,6-LPAP, 1.61 V for 2,7-PKP, and 1.64 V for 2,7-PAP respectively. The slightly increased oxidation potential of the 2,7-linked polymers (0.07 eV higher with respect to 3,6-linked polymers) may be caused by the difference of electron-transfer kinetics from the increased planarity. Setting the energy level of Ag/AgCl to be 4.4 eV below the vacuum level, and determining the band gap from the absorption onset, the HOMO and LUMO values for 3,6-PKP were estimated to be 5.55 eV and 2.45 eV respectively. The corresponding values were 5.71 and 2.65 eV for 3,6-LPAP, 5.56 and 2.72 eV for 2,7-PKP, 5.89 and 2.81 eV for 2,7-PAP respectively.

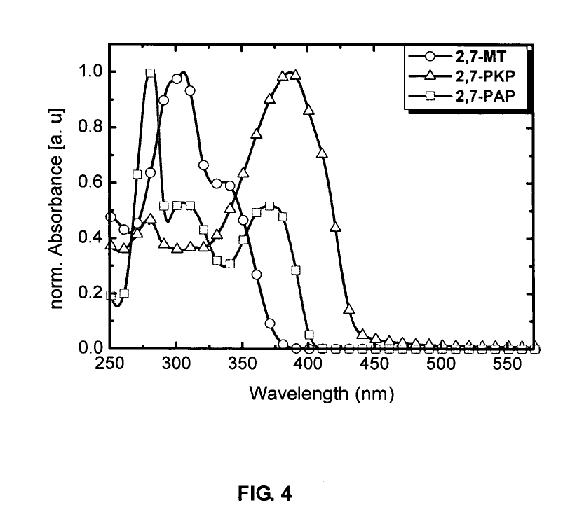

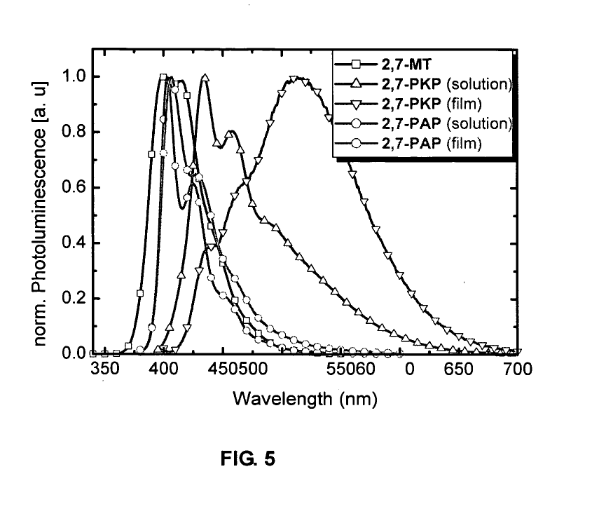

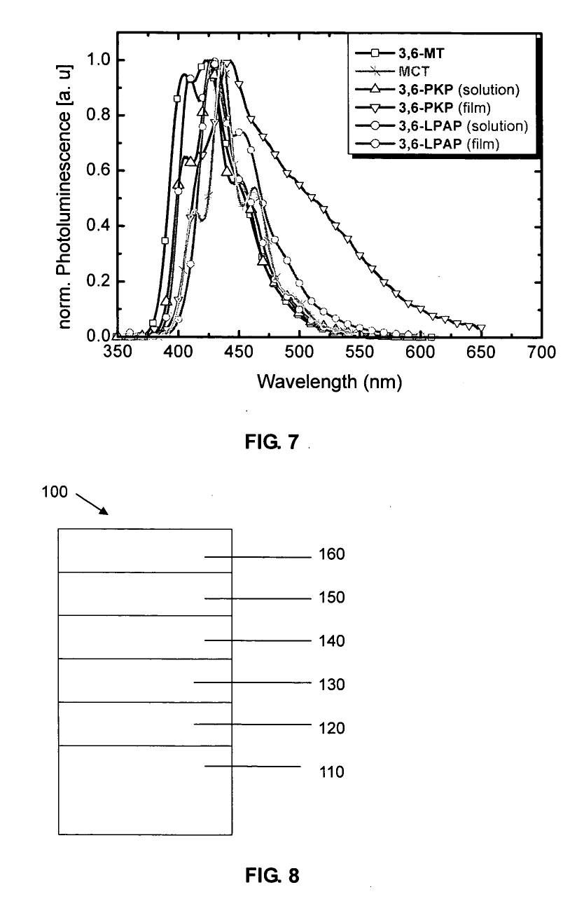

Photophysical Properties. The UV-vis and photoluminescence properties of all the polymers as well as their model compounds were investigated in THF solution and in thin films as depicted in FIGS. 4-7. Transparent and uniform polymer films were prepared on quartz by spin-casting from THF solutions at room temperature. The absorption and PL emission spectral data for all the materials are summarized in Table 1. As shown in FIG. 4, the polymer 2,7-PKP gave two distinct absorption peaks with maxima at 278 nm and 387 nm. The former peak can be assigned to absorption from monomeric benzene units, whereas the lower-energy peak is mainly associated with a π-π* transition originating from the conjugated polymer backbone. The absorption peaks of the polymer 2,7-PAP are remarkably similar to those of 2,7-PKP but a new maximum is observed at 306 nm and the π-π* transition originating from the main chain (λₘₐₓ=370 nm) is hypsochromically shifted relative to that of 2,7-PKP. Not wishing to be bound by theory, the small blue-shift in absorbance maximum for 2,7-PAP when compared with 2,7-PKP can be attributed to slightly reduced conjugation in the former due to the aryl substituents at 9,10 positions of phenanthrene. Again, not wishing to be bound by theory, the new UV-vis maximum at 306 nm for 2,7-PAP seems to originate from the additional chromophore formed by introduction of aryl substituents at 9,10-positions which is supported by the fact that the same peak (λₘₐₓ=306 nm) also appears in the model trimer 2,7-MT. In the photoluminescence spectra (FIG. 5), a large bathochromic shift and broad bands are observed for 2,7-PKP with an emission maximum at 434 nm in solution and a shoulder at 458 nm. However, in thin film, the emission maximum is highly red-shifted to 513 nm indicative of strong aggregation with alkyl substituents at 9,10-positions of phenanthrene. The polymer 2,7-PAP in THF solution shows a pure blue PL emission with a sharp peak centered at 403 nm and shoulder peaks at 425 nm and 451 nm. The spectrum in solid state is almost identical to that in solution, and no bathochromic shift is observed, which indicates that there is almost no change in the conformation of the 2,7-PAPs' backbone from the solution to the solid state and the solubilizing phenyl side-chains suppress the aggregation in the solid state.

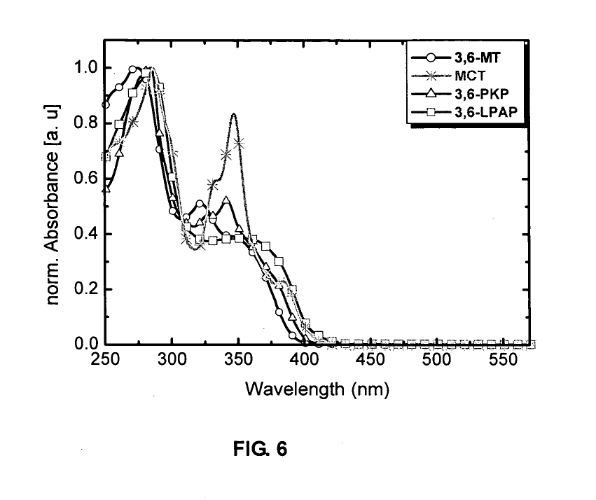

In the case of the 3,6-linked polymers, the absorption spectrum of 3,6-LPAP in THF solution shows two distinguishable contributions: one peak at 285 nm due to benzene ring absorption and a second broad band in the 343-357 nm range. In the case of 3,6-LPAP, the aryl substituents at 9,10-positions can also enter into conjugation along the polymer chain and hence the broad absorption band can be attributed to the existence of multiple chromophores. Moreover, the narrower band of the polymer 3,6-PKP compared to that of 3,6-LPAP also supports this hypothesis. The macrocyclic trimer MCT shows a sharp absorption maximum at 347 nm which is also present in 3,6-PKP generated by the Yamamoto route indicative of the formation of a significant amount of macrocycle during its synthesis (FIG. 6). However this maximum is absent in the absorption spectrum of 3,6-LPAP formed by the Suzuki polycondensation route since this avoids the formation of the cyclic trimer. MCT shows pure blue emission with the peak centered at 436 nm in solution. The PL spectrum of 3,6-PKP in THF solution is almost identical with that of macrocyclic trimer and shows aggregation phenomena in solid state very similar to that of 2,7-PKP due to increased backbone planarity. The polymer 3,6-LPAP in THF solution also exhibits a pure blue PL emission with two apparent peaks at 409 and 429 nm with weak shoulder peak at 453 nm and in solid state display the same peak centered at 429 nm as in solution with a shoulder peak at 451 nm. This result confirmed that the side phenyl solubilizing group can suppress the aggregation in the solid state similar to 2,7-PAP. The slight increase in the relative intensity of the shoulder peak can be ascribed to stronger self-absorption in film.

TABLE 1
Optical and electrochemical properties of the polymers and model compound

| | | | | | | Optical |
|---|---|---|---|---|---|---|
| | Solution λₘₐₓ (nm) | | Film λₘₐₓ (nm) | HOMO | LUMO | bandgap^{a} |
| compound | Absorption | Emission | Emission | (eV) | (eV) | (eV) |
| 2,7-MT | 306, 336 | 399 (416) | | | | |
| 2,7-PKP | 387 | 434 (458) | 513 | −5.56 | −2.92 | 2.84 |
| 2,7-PAP | 306, 370 | 403 (425, 451) | 407 (429) | −5.89 | −2.81 | 3.08 |
| 3,6-MT | 322 (346) | 405, 422 | | | | |
| MCT | 347 (385) | 413, 436 (463) | | | | |
| 3,6-PKP | 342 | 407, 426 (451) | 443 | −5.69 | −2.59 | 3.10 |
| 3,6-LPAP | 343-357 | 409, 429 (453) | 429 (451) | −5.71 | −2.65 | 3.08 |

^{a}Estimated from a combination of CV data and the onset wavelength of optical absorption in solution.
Peaks that appear as shoulders or weak bands are shown in parentheses

Electroluminescence (EL) Properties. A series of 3,6- and 2,7-onjugated poly(phenanthrene)s have been synthesized for the first time by either Yamamoto or Suzuki-type polycondensation. The introduction of solubilizing alkyl or aryl substituents at 9,10-positions of phenanthrene render these materials soluble and processable. In the case of 2,7-linked polymers, it is found that alkyl substituents at 9,10-positions lead to aggregation in the solid state whereas the introduction of aryl substituents completely suppress aggregation as evidenced by the almost identical emission in solution and solid state for the latter. In the case of 3,6-linked polymers, it is found that Yamamoto polymerization leads to the formation of substantial amounts of macrocyclic trimer in the reaction. However, it was shown that by using a Suzuki-type polycondensation, soluble higher molecular weight materials can be obtained for poly(3,6-phenanthrene)s. Both 2,7- and 3,6-linked polyphenanthrenes with aryl substituents emit in the blue both in solution and film (with an emission maximum of 425 nm for 2,7-PAP and 429 nm for 3,6-LPAP in film). The obtained polymers possess good solubility, film-forming ability, thermal stability, and moderately high photoluminescence efficiency.

Electronic Device

The term “buffer layer” or “buffer material” is intended to materials that are electrically conductive or semiconductive and may have one or more functions in an organic electronic device, including but not limited to, planarization of the underlying layer, charge transport and/or charge injection properties, scavenging of impurities such as oxygen or metal ions, and other properties to facilitate or to improve the performance of the organic electronic device. Buffer Materials may be polymers, solutions, dispersions, suspensions, emulsions, colloidal mixtures, or other compositions.

“Photoactive” refers to a material that emits light when activated by an applied voltage (such as in a light emitting diode or device, or chemical cell) or responds to radiant energy and generates a signal with or without an applied bias voltage (such as in a photodetector).

“Hole transport” when referring to a layer, material, member, or structure, is intended to mean that such layer, material, member, or structure facilitates migration of positive charges through the thickness of such layer, material, member, or structure with relative efficiency and small loss of charge.

“Electron transport” means when referring to a layer, material, member or structure, that such a layer, material, member or structure promotes or facilitates migration of negative charges through such a layer, material, member or structure into another layer, material, member or structure.

“Charge transport” means, when referring to a layer or material, member or structure, that such a layer, material, member or structure promotes or facilitates the migration of charges, either negative or positive, through such layer, material, member or structure into another layer, material, member or structure.

FIG. 8 is an exemplary electronic device, an organic light-emitting diode (OLED) display that includes at least two organic active layers positioned between two electrical contact layers. The electronic device 100 includes one or more layers 120 and 130 to facilitate the injection of holes from the anode layer 110 into the photoactive layer 140. In general, when two layers are present, the layer 120 adjacent the anode is called the hole injection layer or buffer layer. The layer 130 adjacent to the photoactive layer is called the hole transport layer. An optional electron transport layer 150 is located between the photoactive layer 140 and a cathode layer 160. Depending on the application of the device 100, the photoactive layer 140 can be a light-emitting layer that is activated by an applied voltage (such as in a light-emitting diode or light-emitting electrochemical cell), a layer of material that responds to radiant energy and generates a signal with or without an applied bias voltage (such as in a photodetector). The device is not limited with respect to system, driving method, and utility mode.

The phenanthrene polymers described herein can be used in the hole transport layer 130, as the light-emitting or photosensitive material in the photoactive layer 140, or as a host for other light-emitting/photosensitive materials in layer 140.

The other layers in the device can be made of any materials which are known to be useful in such layers. The device may include a support or substrate (not shown) that can be adjacent to the anode layer 110 or the cathode layer 150. Most frequently, the support is adjacent the anode layer 110. The support can be flexible or rigid, organic or inorganic. Generally, glass or flexible organic films are used as a support. The anode layer 110 is an electrode that is more efficient for injecting holes compared to the cathode layer 160. The anode can include materials containing a metal, mixed metal, alloy, metal oxide or mixed oxide. Suitable materials include the mixed oxides of the Group 2 elements (i.e., Be, Mg, Ca, Sr, Ba, Ra), the Group 11 elements, the elements in Groups 4, 5, and 6, and the Group 8-10 transition elements. If the anode layer 110 is to be light transmitting, mixed oxides of Groups 12, 13 and 14 elements, such as indium-tin-oxide, may be used. As used herein, the phrase “mixed oxide” refers to oxides having two or more different cations selected from the Group 2 elements or the Groups 12, 13, or 14 elements. Some non-limiting, specific examples of materials for anode layer 110 include, but are not limited to, indium-tin-oxide (“ITO”), aluminum-tin-oxide, gold, silver, copper, and nickel. The anode may also comprise an organic material such as polyaniline, polythiophene, or polypyrrole.

The anode layer 110 may be formed by a chemical or physical vapor deposition process or spin-cast process. Chemical vapor deposition may be performed as a plasma-enhanced chemical vapor deposition (“PECVD”) or metal organic chemical vapor deposition (“MOCVD”). Physical vapor deposition can include all forms of sputtering, including ion beam sputtering, as well as e-beam evaporation and resistance evaporation. Specific forms of physical vapor deposition include rf magnetron sputtering and inductively-coupled plasma physical vapor deposition (“IMP-PVD”). These deposition techniques are well known within the semiconductor fabrication arts.

Usually, the anode layer 110 is patterned during a lithographic operation. The pattern may vary as desired. The layers can be formed in a pattern by, for example, positioning a patterned mask or resist on the first flexible composite barrier structure prior to applying the first electrical contact layer material. Alternatively, the layers can be applied as an overall layer (also called blanket deposit) and subsequently patterned using, for example, a patterned resist layer and wet chemical or dry etching techniques. Other processes for patterning that are well known in the art can also be used. When the electronic devices are located within an array, the anode layer 110 typically is formed into substantially parallel strips having lengths that extend in substantially the same direction.

The buffer layer 120 functions to facilitate injection of holes into the photoactive layer and to smoothen the anode surface to prevent shorts in the device. The buffer layer is typically formed with polymeric materials, such as polyaniline (PANI) or polyethylenedioxythiophene (PEDOT), which are often doped with protonic acids. The protonic acids can be, for example, poly(styrenesulfonic acid), poly(2-acrylamido-2-methyl-1-propanesulfonic acid), and the like. The buffer layer 120 can comprise charge transfer compounds, and the like, such as copper phthalocyanine and the tetrathiafulvalene-tetracyanoquinodimethane system (TTF-TCNQ). In one embodiment, the buffer layer 120 is made from a dispersion of a conducting polymer and a colloid-forming polymeric acid. Such materials have been described in, for example, published U.S. patent applications 2004-0102577 and 2004-0127637.

The buffer layer 120 can be applied by any deposition technique. In one embodiment, the buffer layer is applied by a solution deposition method. In one embodiment, the buffer layer is applied by a continuous solution deposition method.

The hole transport layer 130 can comprise a phenanthrene polymer. Examples of other hole transport materials for optional layer 130 have been summarized for example, in Kirk-Othmer Encyclopedia of Chemical Technology, Fourth Edition, Vol. 18, p. 837-860, 1996, by Y. Wang. Both hole transporting molecules and polymers can be used. Commonly used hole transporting molecules include, but are not limited to: 4,4′,4″-tris(N,N-diphenyl-amino)-triphenylamine (TDATA); 4,4′,4″-tris(N-3-methylphenyl-N-phenyl-amino)-triphenylamine (MTDATA); N,N′-diphenyl-N,N′-bis(3-methylphenyl)-[1,1′-biphenyl]-4,4′-diamine (TPD); 1,1-bis[(di-4-tolylamino) phenyl]cyclohexane (TAPC); N,N′-bis(4-methylphenyl)-N,N′-bis(4-ethylphenyl)-[1,1′-(3,3′-dimethyl)biphenyl]-4,4′-diamine (ETPD); tetrakis-(3-methylphenyl)-N,N,N′,N′-2,5-phenylenediamine (PDA); α-phenyl-4-N,N-diphenylaminostyrene (TPS); p-(diethylamino)benzaldehyde diphenylhydrazone (DEH); triphenylamine (TPA); bis[4-(N,N-diethylamino)-2-methylphenyl](4-methylphenyl)methane (MPMP); 1-phenyl-3-[p-(diethylamino)styryl]-5-[p-(diethylamino)phenyl]pyrazoline (PPR or DEASP); 1,2-trans-bis(9H-carbazol-9-yl)cyclobutane (DCZB); N,N,N′, N′-tetrakis(4-methylphenyl)-(1,1′-biphenyl)-4,4′-diamine (TTB); N,N′-bis(naphthalen-1-yl)-N,N′-bis-(phenyl)benzidine (α-NPB); and porphyrinic compounds, such as copper phthalocyanine. Commonly used hole transporting polymers include, but are not limited to, polyvinylcarbazole, (phenylmethyl)polysilane, poly(dioxythiophenes), polyanilines, and polypyrroles. It is also possible to obtain hole transporting polymers by doping hole transporting molecules such as those mentioned above into polymers such as polystyrene and polycarbonate.

The hole transport layer 130 can be applied by any deposition technique. In one embodiment, the hole transport layer is applied by a solution deposition method. In one embodiment, the hole transport layer is applied by a continuous solution deposition method.

Any organic electroluminescent (“EL”) material can be used in the photoactive layer 140, including, but not limited to, small molecule organic fluorescent compounds, fluorescent and phosphorescent metal complexes, conjugated polymers, and mixtures thereof. Examples of fluorescent compounds include, but are not limited to, pyrene, perylene, rubrene, coumarin, derivatives thereof, and mixtures thereof. Examples of metal complexes include, but are not limited to, metal chelated oxinoid compounds, such as tris(8-hydroxyquinolato)aluminum (Alq3); cyclometalated iridium and platinum electroluminescent compounds, such as complexes of iridium with phenylpyridine, phenylquinoline, or phenylpyrimidine ligands as disclosed in Petrov et al., U.S. Pat. No. 6,670,645 and Published PCT Applications WO 03/063555 and WO 2004/016710, and organometallic complexes described in, for example, Published PCT Applications WO 03/008424, WO 03/091688, and WO 03/040257, and mixtures thereof. Electroluminescent emissive layers comprising a charge carrying host material and a metal complex have been described by Thompson et al., in U.S. Pat. No. 6,303,238, and by Burrows and Thompson in published PCT applications WO 00/70655 and WO 01/41512. Examples of conjugated polymers include, but are not limited to poly(phenylenevinylenes), polyfluorenes, poly(spirobifluorenes), polythiophenes, poly(p-phenylenes), copolymers thereof, and mixtures thereof. In one embodiment, the electroluminescent material is a phenanthrene polymer described herein. In one embodiment, the photoactive layer comprises an electroluminescent material is doped into a phenanthrene polymer.

The photoactive layer 140 can be applied by any deposition technique. In one embodiment, the photoactive layer is applied by a solution deposition method. In one embodiment, the photoactive layer is applied by a continuous solution deposition method.

Optional layer 150 can function both to facilitate electron injection/transport, and can also serve as a confinement layer to prevent quenching reactions at layer interfaces. More specifically, layer 150 may promote electron mobility and reduce the likelihood of a quenching reaction if layers 140 and 160 would otherwise be in direct contact. Examples of materials for optional layer 150 include, but are not limited to, metal-chelated oxinoid compounds (e.g., Alq₃ or the like); phenanthroline-based compounds (e.g., 2,9-dimethyl-4,7-diphenyl-1,10-phenanthroline (“DDPA”), 4,7-diphenyl-1,10-phenanthroline (“DPA”), or the like); azole compounds (e.g., 2-(4-biphenylyl)-5-(4-t-butylphenyl)-1,3,4-oxadiazole (“PBD” or the like), 3-(4-biphenylyl)-4-phenyl-5-(4-t-butylphenyl)-1,2,4-triazole (“TAZ” or the like); other similar compounds; or any one or more combinations thereof. Alternatively, optional layer 150 may be inorganic and comprise BaO, LiF, Li₂O, or the like.

The cathode 160, is an electrode that is particularly efficient for injecting electrons or negative charge carriers. The cathode layer 160 can be any metal or nonmetal having a lower work function than the first electrical contact layer (in this case, the anode layer 110). As used herein, the term “lower work function” is intended to mean a material having a work function no greater than about 4.4 eV. As used herein, “higher work function” is intended to mean a material having a work function of at least approximately 4.4 eV.

Materials for the cathode layer can be selected from alkali metals of Group 1 (e.g., Li, Na, K, Rb, Cs,), the Group 2 metals (e.g., Mg, Ca, Ba, or the like), the Group 12 metals, the lanthanides (e.g., Ce, Sm, Eu, or the like), and the actinides (e.g., Th, U, or the like). Materials such as aluminum, indium, yttrium, and combinations thereof, may also be used. Specific non-limiting examples of materials for the cathode layer 160 include, but are not limited to, barium, lithium, cerium, cesium, europium, rubidium, yttrium, magnesium, samarium, and alloys and combinations thereof.

The cathode layer 160 is usually formed by a chemical or physical vapor deposition process.

In other embodiments, additional layer(s) may be present within organic electronic devices.

The different layers may have any suitable thickness. Inorganic anode layer 110 is usually no greater than approximately 500 nm, for example, approximately 10-200 nm; buffer layer 120, and hole transport layer 130 are each usually no greater than approximately 250 nm, for example, approximately 50-200 nm; photoactive layer 140, is usually no greater than approximately 1000 nm, for example, approximately 50-80 nm; optional layer 150 is usually no greater than approximately 100 nm, for example, approximately 20-80 nm; and cathode layer 160 is usually no greater than approximately 100 nm, for example, approximately 1-50 nm. If the anode layer 110 or the cathode layer 160 needs to transmit at least some light, the thickness of such layer may not exceed approximately 100 nm.

Experimental

General. Commercially available materials were used as received unless noted otherwise. ¹H and ¹³C NMR spectra were recorded on a Bruker 300 MHz and 500 MHz spectrometer and referenced to the solvent peak (CDCI₃, 7.26 and 77.0 ppm). Gel Permeation Chromatography (GPC) analysis against polystyrene standards was performed in THF on a Waters high pressure GPC assembly with an M590 pump, microstyragel columns of 10⁵, 10⁴, 10³, 500 and 100 Å and a refractive index detector. UV-visible absorption spectra were recorded on a Perkin-Elmer Lambda 15 spectrophotometer. Photoluminescence spectra were recorded on a SPEX Fluorolog 2 Type F212 steady state fluorometer, using a 450 W xenon arc lamp as excitation source and a PMT R 508 photomultiplier as detector system. Thermogravimetric analysis and differential scanning calorimetry (DSC) measurements were carried out on a Mettler 500 thermogravimetric analyser and Mettler DSC 30 calorimeter respectively. CV was performed on an EG&G Princeton Applied Research Potentiostat, Model 270 on 2 μm thick films deposited by solution-coating onto pre-cleaned ITO as a working electrode with an area of 0.2 cm². After coating, the films were dried in a vacuum oven for 10 min. The measurements were carried out in acetonitrile solutions containing 0.1 M of tetrabutylammonium perchlorate as the supporting electrolyte, using Ag/AgCl as the reference electrode and a platinum wire as the counter electrode and an internal ferrocene/ferrocenium (FOC) standard.

General procedure for the synthesis of benzoyl chlorides. A flask equipped with a reflux condenser and a drying tube was charged with benzoic acid and benzene (50 mL). To this mixture was added oxalyl chloride (1.5 equiv) and one drop of N,N-dimethylformamide (catalyst). The reaction mixture was heated at 80° C. overnight (bubbling observed), then the reaction was cooled and the solvent was removed in vacuo. The crude solid was dissolved in benzene (20 mL) and stirred with calcium hydride for 1 h and the filtered. The benzene was removed in vacuo to give benzoyl chloride compound.

General procedure for Ullmann coupling. To the halide compound in dry N,N-dimethylformamide, copper powder (2.3 equiv.) was added under argon and then heated at 120° C. for 12-24 h. The mixture was filtered and extracted into ether, washed with brine and dried over MgSO₄. The crude product was then chromatographed on silica gel using an appropriate eluent.

General Procedure for Yamamoto polymerization. Bis(cyclooctadiene)nickel (2.4 equiv), cyclooctadiene (2.4 equiv), and 2,2′-bipyridine (2.4 equiv) were dissolved in dry toluene (3.5-5 mL) and dry N,N-dimethylformamide (3.5-5 mL) in a Schlenk flask within a glovebox. The mixture was heated at 60° C. with stirring under argon for 20 min to generate the catalyst, and then a solution of the monomer in dry toluene (7-10 mL) was added. The reaction was heated at 75° C. for 2 days. Then a mixture of toluene (2-4 mL) and bromobenzene (0.10 mL) was added and the mixture was heated at 75° C. for an additional 12 h. The mixture was then poured into a mixture of methanol and concentrated hydrochloric acid (1:1, 300 mL) and stirred for 4 h. The precipitated white solid was redissolved in THF (10 mL) and added dropwise to methanol (200 mL). The resulting solid was filtered off and subjected Soxhlet extraction for 2 days in acetone. The residue was then redissolved in THF and precipitated again from methanol, filtered, washed with methanol, and dried.

General Procedure for Friedel-Crafts acylation. To the benzoyl chloride in 20 mL of dichloromethane, aluminum chloride (1.5 equiv) and decyl benzene (1.9 equiv.) was added and stirred at room temperature for 12-18 h and then quenched with aqueous 2 M HCl. The mixture was then extracted into DCM and washed with brine. The crude product was then chromatographed on silica gel with an appropriate eluent.

General Procedure the cyclization of dibenzoylbiphenyl units. A solution of boron trichloride in methylene chloride (1.0 M, 2.0 equiv) was introduced to a mixture of dibenzoylbiphenyl derivative and tricyclohexyltin sulfide (2.2 equiv) in dry toluene at room temperature under argon. After stirring for 10 min at room temperature, the mixture was heated at 110° C. overnight. The reaction was then quenched by adding 2 M HCl and then extracted with diethyl ether and washed with brine. The crude product was chromatographed on silica with an eluent and further purified by twice recrystallization from THF in ethanol and dichloromethane in ethanol respectively.

Synthesis of 1-(2,5-Dibromo-phenyl)-undecan-1-one, 1. To a solution of tert-butyllithium (48.9 ml, 84.0 mmol, 1.7 M in pentane) in dry ether (30ml) at −78° C. was added 1-iododecane (10 ml, 30 mmol) dropwise. This solution was stirred for 1 h at −78° C. The cold bath was removed and the slurry was transferred via cannula to a slurry of copper (I) cyanide (4.83 g 54.0 mmol) in dry THF (105 mL) at −78° C. The reaction mixture was allowed to stir for 4 h, then 2,5-dibromo-benzoyl chloride (7.45 g, 25 mmol) in dry THF (60 ml) was cooled to 0° C. and added via cannula to the −78° C. solution and the mixture stirred for 1 h at this temperature. The reaction was then quenched by the addition of a 9:1 mixture of saturated ammonium chloride and ammonium hydroxide solution and the mixture filtered. The aqueous layer was extracted with ether, washed with brine and dried over MgSO₄. The crude product was chromatographed on silica gel using 0-5% ethylacetate in hexane as eluent and further purified by recrystallization from hexane. Isolated yield=7.0 g (70%) as white needlelike crystals. ¹H NMR (CDCl₃, 300 MHz): δ 7.42 (ddd, J=10.8, 7.0, and 2.7 Hz, 3H), 2.90 (t, J=7.2 Hz, 2H), 1.77-1.61 (m, 2H), 1.55-1.29 (m, 14H), 0.88 (t, J=6.5 Hz, 3H). ¹³C NMR (CDCl₃, 300 MHz): 202.61, 143.19, 134.56, 133.77, 130.62, 120.98, 116.73, 42.28, 31.44, 29.10, 29.00, 28.92, 28.85, 28.69, 23.50, 22.23, 13.67. FDMS (m/z): 404.2 (M^{+*}). Elemental analysis: Calculated for C₁₇H₂₄Br₂O: C, 50.52; H, 5.99; Br, 39.54; O, 3.96; Found: C, 71.27; H, 9.73.

Synthesis of 1-(4,4′-Dibromo-2′-undecanoyl-biphenyl-2-yl)-undecan-1-one, 2. Compound 1 (6.0 g, 14.8 mmol) was used in the Ullmann coupling and purified by 0-25% dichloromethane in hexane as eluent. Isolated yield=2.1 g (43%) as a yellow oil. ¹H NMR (CDCl₃, 300 MHz): δ 7.78 (d, J=2.0 Hz, 2H), 7.59 (d, J=2.0 Hz, 1H), 7.56 (d, J=2.0 Hz, 1H), 6.99 (d, J=8.2 Hz, 2H), 2.69-2.53 (m, 4H), 1.60-1.41 (m, 4H), 1.35-1.15 (m, 28H), 0.89 (m, 6H). ¹³C NMR (CDCl₃, 300 MHz): 202.27, 139.96, 137.92, 133.38, 131.92, 130.79, 121.57, 41.01, 31.64, 29.30, 29.20, 29.10, 29.05, 28.82, 23.71, 22.42, 13.86. FDMS (m/z): 648.5 (M^{+*}). Elemental analysis: Calculated for C₃₄H₄₈Br₂O₂: C, 62.97; H, 7.46; Br, 24.64; O, 4.93; Found: C, 71.27; H, 9.73.

Polymer 3. The dibromide monomer 2 (428 mg, 0.66 mmol) was used in this polymerization and isolated yield of polymer 3=250 mg (78%). GPC analysis Mₙ=2.32×10⁴ g/mol, M_{w}=4.25×10⁴ g/mol, and D=1.82 (against PPP standard); Mₙ=3.67×10⁴ g/mol, M_{w}=8.17×10⁴ g/mol, and D=2.23 (against PS standard). ¹H NMR (CDCl₃, 300 MHz): δ 8.10-7.72 (br m, 5H), 7.45-7.30 (br m, 1H), 2.80-2.65 (br m, 4H), 1.67-1.50 (br m, 4H), 1.45-1.21 (br m, 28H), 0.97-0.73 (br m, 6H). Elemental analysis: Calculated for C₃₄H₄₈O₂: C, 83.55; H, 9.90; O, 6.55; Found: C, 71.27; H, 9.73.

Polymer 2,7-PKP. TiCl₃ (0.23 g, 1.47 mmol) was added to a Schlenk flask in a glovebox along with 10 mL of dry THF and LiAlH₄ (0.75 mL, 1.0 M in THF) and the mixture was then heated at reflux for 1 h. The reaction was cooled to room temperature and a solution of the polymer 3 (30 mg, 0.06 mmol) in dry THF (10 mL) was slowly added and then heated at reflux for 3 days. The mixture was then poured into a mixture of methanol and 2 M HCl (1:1, 300 mL) and stirred for 4 h. The precipitated solid was redissolved in THF (20 mL) and added dropwise to methanol (200 mL). The resulting solid was filtered off and subjected Soxhlet extraction for 1 day in acetone and then dried. Isolated yield of polymer 2,7-PKP=27 mg (95%). GPC analysis Mₙ=4.68×10⁴ g/mol, M_{w}=9.78×10⁴ g/mol, and D=2.09 (against PPP standard); Mₙ=8.11×10⁴ g/mol, M_{w}=2.12×10⁵ g/mol, and D=2.61 (against PS standard). ¹H NMR (CDCl₃, 300 MHz): δ 8.10-7.72 (br m, 5H), 7.45-7.30 (m, 1H), 2.80-2.65 (m, 4H), 1.67-1.50 (m, 4H), 1.45-1.21 (m, 28H), 0.97-0.73 (m, 9H). Elemental analysis: Calculated for C₃₄H₄₈: C, 89.41; H, 10.59; Found: C, 71.27; H, 9.73.

Synthesis of 1-(2-Bromo-phenyl)-undecan-1-one, 4. 2-bromo-benzoyl chloride (11.9 mL, 91.1 mmol) was used according to the procedure for 1 and purified by 0-5% ethylacetate in hexane as eluent. Isolated yield=24.7 g (83%) as a yellow solid. ¹H NMR (CDCl₃, 300 MHz): δ 7.62 (d, J=7.8 Hz, 1H), 7.38 (d, J=4.8 Hz, 2H), 7.30 (q, J=3.6 Hz, 1H), 2.95 (t, J=7.2 Hz, 2H), 1.75-1.62 (m, 2H), 1.40-1.21 (m, 14H), 0.91 (t, J=5.2 Hz, 3H). ¹³C NMR (CDCl₃, 300 MHz): 205.03, 141.60, 133.06, 130.75, 127.72, 126.84, 118.05, 42.26, 31.39, 29.21, 29.06, 28.97, 28.81, 28.66, 23.58, 22.18, 13.61. FDMS (m/z): 325.3 (M^{+*}). Elemental analysis: Calculated for C₁₇H₂₅BrO: C, 62.77; H, 7.75; Br, 24.56; O, 4.92; Found: C, 71.27; H, 9.73.

Synthesis of 1-(2′-Undecanoyl-biphenyl-2-yl)-undecan-1-one, 5. The compound 4 (10.0 g, 30.7 mmol) was used in the Ullmann coupling and purified by 0-33% dichloromethane in hexane as eluent. Isolated yield=4.2 g (55%) as a yellow oil. ¹H NMR (CDCl₃, 300 MHz): 6 7.64 (dd, J=6.1 and 2.9 Hz, 2H), 7.43 (m, 4H), 7.14 (m, 2H), 2.64-2.47 (m, 4H), 1.55-1.41 (m, 4H), 1.30-1.11 (m, 28H), 0.89 (m, 6H). ¹³C NMR (CDCl₃, 300 MHz): 204.78, 139.81, 139.27, 130.57, 130.27, 127.83, 127.37, 41.46, 31.67, 29.33, 29.23, 29.12, 29.08, 28.91, 23.99, 22.45, 13.88. FDMS (m/z): 490.7 (M^{+*}). Elemental analysis: Calculated for C₃₄H₅₀O2: C, 83.21; H, 10.27; O, 6.52; Found: C, 71.27; H, 9.73.

Synthesis of 9 3,6-Dibromo-9,10-bis-decyl-phenanthrene, 6. TiCl₃ (2.38 g, 15.5 mmol) was added to a Schlenk flask in a glovebox along with 10 mL of dry THF and 7.74 mL of LiAlH₄ (1.0 M in THF). The mixture was heated at reflux for 1 h and then cooled, a solution of 5 (3.8 g, 7.74 mmol) in dry THF (10 mL) was slowly added and heated at reflux for 16 h. The reaction was then quenched by adding 2 M HCl, and then extracted with dichloromethane. The organic layers were dried over MgSO₄, and the solvent was evaporated. The crude product was then chromatographed on silica gel using hexane as eluent. Isolated yield=2.5 g (70%) as white needlelike crystals. ¹H NMR (CDCl₃, 300 MHz): δ 8.74 (d, J=9.6 Hz, 2H), 8.13 (d, J=9.6 Hz, 2H), 7.61 (m, 4H), 3.15 (t, J=7.8 Hz, 4H), 1.71-1.55 (m, 4H), 1.52-1.31 (m, 28H), 0.95-0.82 (m, 6H). ¹³C NMR (CDCl₃, 300 MHz): 133.70, 131.14, 129.59, 126.30, 125.10, 124.45, 122.70, 31.72, 20.52, 30.22, 29.51, 29.47, 29.35, 29.17, 22.49, 13.91. FDMS (m/z): 458.7 (M^{+*}). Elemental analysis: Calculated for C₃₄H₅₀: C, 89.01; H, 10.99; Found: C, 71.27; H, 9.73.

The bromination was performed using a solution of 9,10-Bis-decyl-phenanthrene (580 mg, 1.26 mmol) and catalytic amount of iodine in 10 mL CCl₄. To this mixture, bromine (0.4 g, 2.52 mmol) was added dropwise at 0° C. The reaction mixture was slowly allowed to warm to room temperature overnight. Additional bromine (0.1 g, 0.63 mmol) was then added with stirring and the reaction was monitored by FDMS, which showed nearly quantitative formation of the dibromide after 12 h. The reaction was quenched by the addition of aqueous Na₂S₂O₅ solution and then extracted into DCM, washed with brine and dried. The crude product was chromatographed on silica gel using hexane as eluent and further purified by recrystallization from THF in ethanol. Isolated yield=420 mg (54%) as white needlelike crystals. ¹H NMR (CDCl₃, 300 MHz): δ 8.70 (d, J=1.9 Hz, 2H), 7.92 (d, J=8.9 Hz, 2H), 7.70 (dd, J=8.9 and 1.9 Hz, 2H), 3.06 (t, J=8.6 Hz, 4H), 1.70-1.50 (m, 4H), 1.47-1.21 (m, 28H), 0.97-0.85 (m, 6H). ¹³C NMR (CDCl₃, 300 MHz): 133.77, 129.90, 129.80, 126.12, 125.27, 119.59, 31.48, 30.22, 29.89, 29.21, 29.07, 28.93, 22.26, 13.68. FDMS (m/z): 616.5 (M^{+*}). Elemental analysis: Calculated for C34H₄₈Br₂: C, 66.23; H, 7.85; Br, 25.92; Found: C, 71.27; H, 9.73.

Polymer of 3,6-PKP. The dibromide monomer 6 (262 mg, 0.425 mmol) was used in this polymerization and isolated yield of polymer 3,6-PKP=120 mg (62%). GPC analysis Mₙ=3.15×10³ g/mol, M_{w}=5.10×10³ g/mol, and D=1.62 (against PPP standard); Mₙ=3.68×10³ g/mol, M_{w}=7.21×10³ g/mol, and D=1.96 (against PS standard). ¹H NMR (CDCl₃, 300 MHz): δ 9.35-9.00 (br m, 2H), 8.25-7.95 (br m, 4H), 3.29-32.95 (br m, 4H), 1.85-1.10 (br m, 32H), 1.02-0.78 (br m, 6H). Elemental analysis: Calculated for C₃₄H₄₈: C, 89.41; H, 10.59; Found: C, 71.27; H, 9.73.

Synthesis of (4-Chloro-2-iodo-phenyl)-(4-decyl-phenyl)-methanone, 7. 4-Chloro-2-iodo-benzoyl chloride (2.5 g, 8.31 mmol) was used in Friedel-Crafts acylation and purified by 0-5% ethylacetate in hexane as eluent. Isolated yield=3.7 g (92%) as a yellow oil. ¹H NMR (CDCl₃, 300 MHz): δ 7.99 (d, J=1.9 Hz, 1H), 7.77 (d, J=8.3 Hz, 2H), 7.48 (dd, J=8.2 and 1.9 Hz, 1H), 7.31 (t, J=8.3 Hz, 3H), 2.73 (t, J=7.8 Hz, 2H), 1.77-1.63 (m, 2H), 1.45-1.27 (m, 14H), 0.94 (t, J=6.9 Hz, 3H). ¹³C NMR (CDCl₃, 300 MHz): 195.33, 149.39, 142.36, 138.54, 135.43, 132.43, 129.99, 128.60, 128.22, 127.46, 92.03, 35.55, 31.30, 30.43, 29.00, 28.95, 28.85, 28.72, 22.09, 13.53. FDMS (m/z): 482.8 (M^{+*}). Elemental analysis: Calculated for C₂₃H₂₈ClIO: C, 57.21; H, 5.85; Cl, 7.34; I, 26.28; O, 3.31; Found: C, 71.27; H, 9.73.

Synthesis of [5-Chloro-2′-(4-decyl-benzoyl)-biphenyl-2-yl]-(4-decyl-phenyl)-methanone, 8. Compound 7 (3.5 g, 7.26 mmol) was used in Ullmann coupling and purified by 0-7% ethylacetate in hexane as eluent and further purified by twice recrystallization from hexane in ethanol. Isolated yield=1.7 g (66%) as a yellow solid. ¹H NMR (CDCl₃, 300 MHz): δ 7.51 (d, J=8.2 Hz, 4H), 7.37 (t, J=1.2 Hz, 2H), 7.30 (d, J=1.2 Hz, 4H), 7.31 (d, J=8.2 Hz, 4H), 2.53 (t, J=7.9 Hz, 4H), 1.62-1.51 (m, 4H), 1.37-1.21 (m, 28H), 0.88 (t, J=6.9 Hz, 6H). ¹³C NMR (CDCl₃, 300 MHz): 195.37, 148.50, 140.92, 136.40, 136.06, 134.26, 131.10, 130.50, 130.21, 127.79, 126.88, 35.79, 31.69, 30.87, 29.41, 29.38, 29.26, 29.12, 22.47, 13.89. FDMS (m/z): 710.8 (M^{+*}). Elemental analysis: Calculated for C₄₆H₅₆Cl₂O₂: C, 77.61; H, 7.93; Cl, 9.96; O, 4.50; Found: C, 71.27; H, 9.73.

Synthesis of 3,6-Dichloro-9,10-bis-(4-decyl-phenyl)-phenanthrene, 9. The compound 8 (1.5 g, 2.11 mmol) was used in the cyclisation procedure. Isolated yield=1.2 g (83%) as white needlelike crystals. ¹H NMR (CDCl₃, 300 MHz): δ 8.64 (d, J=2.0 Hz, 2H), 7.55 (d, J=8.8 Hz, 2H), 7.44 (d, J=8.8 and 2.0 Hz, 2H), 7.01 (q, J=8.0 Hz, 8H), 2.55 (t, J=7.8 Hz, 4H), 1.77-1.60 (m, 4H), 1.35-1.20 (m, 28H), 0.88 (t, J=6.8 Hz, 6H). ¹³C NMR (CDCl₃, 300 MHz): 141.19, 137.21, 135.91, 132.69, 130.80, 130.69, 130.09, 129.65, 127.65, 127.51, 122.07, 33.81, 31.93, 31.11, 29.67, 29.37, 29.16, 28.80, 26.74, 22.69, 14.11. FDMS (m/z): 679.1 (M^{+*}). Elemental analysis: Calculated for C₄₆H₅₆Cl₂: C, 81.27; H, 8.30; Cl, 10.43; Found: C, 71.27; H, 9.73.

Polymer of 10. The dichloride monomer 8 (468 mg, 0.66 mmol) was used in this polymerization and isolated yield of polymer 10=300 mg (74%). GPC analysis Mₙ=2.14×10³ g/mol, M_{w}=4.68×10³ g/mol, and D=1.25 (against PPP standard); Mₙ=2.50×10³ g/mol, M_{w}=3.25×10³ g/mol, and D=1.30 (against PS standard). ¹H NMR (CDCl₃, 300 MHz): δ 8.30-7.89 (br m, 2H), 7.87-7.35 (br m, 4H), 7.11-6.85 (br m, 8H), 2.65-2.50 (br m, 4H), 1.65-1.30 (br m, 4H), 1.29-1.21 (br m, 28H), 0.91-0.82 (br m, 6H). Elemental analysis: Calculated for C₄₆H₅₆O₂: C, 86.20; H, 8.81; O, 4.99; Found: C, 71.27; H, 9.73.

Polymer of 3,6-PAR The dichloride monomer 9 (448 mg, 0.66 mmol) was used in this polymerization and isolated yield of polymer 3,6-PAP=230 mg (57%). GPC analysis Mₙ=4.25×10³ g/mol, M_{w}=7.55×10³ g/mol, and D=1.78 (against PPP standard); Mₙ=5.21×10³ g/mol, M_{w}=1.11×10⁴ g/mol, and D=2.10 (against PS standard). ¹H NMR (CDCl₃, 300 MHz): δ 9.81-9.11 (br m, 1H), 8.21-7.71 (br m, 4H), 7.21-6.69 (br m, 9H), 2.67-2.51 (br m, 4H), 1.67-1.21 (br m, 32H), 0.95-0.83 (br m, 6H). Elemental analysis: Calculated for C₄₆H₅₆: C, 90.73; H, 9.27; Found: C, 71.27; H, 9.73.

The polymerization was carried out in very dilute solution (9.4 mM) for synthesis of MCT and purified by 0-25% dichloromethane in hexane as eluent. Isolated yield=50 mg (12%) as a light yellow solid. ¹H NMR (CDCl₃, 300 MHz): δ 9.83 (s, 6H), 8.18 (d, J=8.8Hz, 6H), 7.80 (d, J=8.6Hz, 6H), 7.10 (q, J=8.3Hz, 24H), 2.60 (t, J=7.6Hz, 12H), 1.71-1.61 (m, 12H), 1.39-1.25 (m, 84H), 0.90 (t, J=6.7Hz, 18H). ¹³C NMR (CDCl₃, 300 MHz): 140.51, 136.74, 136.14, 135.07, 131.56, 130.57, 129.96, 127.14, 35.24, 31.54, 30.96, 29.29, 29.16, 28.99, 28.82, 22.30, 13.71. FDMS (m/z): 1825.0 (M^{+*}). Elemental analysis: Calculated for C₁₃₈H₁₆₈: C, 90.73; H, 9.27; Found: C, 71.27; H, 9.73.

Synthesis of (4-Decyl-phenyl)-(2-iodo-phenyl)-methanone, 11. 2-Iodo-benzoyl chloride (5.0 g, 18.7 mmol) was used in Friedel-Crafts acylation and purified by 0-10% ethylacetate in hexane as eluent. Isolated yield=8.1 g (96%) as a yellow oil. ¹H NMR (CDCl₃, 300 MHz): δ 7.92 (dd, J=7.9 and 0.9 Hz, 1H), 7.74 (d, J=8.3 Hz, 2H), 7.43 (dt, J=7.5, 1.1 Hz, 1H), 7.28 (m, 3H), 7.16 (dt, J=7.8 and 1.7 Hz, 1H), 2.68 (t, J=7.7 Hz, 2H), 1.71-1.60 (m, 2H), 1.37-1.27 (m, 14H), 0.89 (t, J=6.7 Hz, 18H). ¹³C NMR (CDCl₃, 300 MHz): 196.64, 149.53, 144.53, 139.49, 133.16, 130.80, 130.51, 128.60, 128.23, 127.59, 92.15, 36.02, 31.78, 30.91, 29.48, 29.44, 29.34, 29.20, 29.18, 22.57, 14.03. FDMS (m/z): 448.1 (M^{+*}). Elemental analysis: Calculated for C₂₃H₂₉IO: C, 61.61; H, 6.52; I, 28.30; O, 3.57; Found: C, 71.27; H, 9.73.

Synthesis of [2′-(4-Decyl-benzoyl)-biphenyl-2-yl]-(4-decyl-phenyl)-methanone, 12. Compound 11 (8.0 g, 17.8 mmol) was used in Ullmann coupling and purified by 0-10% ethylacetate in hexane as eluent. Isolated yield=5.2 g (90%) as a reddish solid. ¹H NMR (CDCl₃, 300 MHz): δ 7.63 (d, J=8.2 Hz, 4H), 7.45-7.35 (m, 8H), 7.05 (d, J=8.2 Hz, 4H), 2.55 (t, J=7.7 Hz, 4H), 1.67-1.57 (m, 4H), 1.37-1.27 (m, 28H), 0.89 (t, J=6.7 Hz, 6H). ¹³C NMR (CDCl₃, 300 MHz): 197.01, 148.16, 139.87, 138.31, 134.78, 131.23, 130.34, 129.59, 129.00, 127.76, 126.37, 35.77, 31.68, 30.84, 29.39, 29.36, 29.25, 29.10, 22.46, 13.89. FDMS (m/z): 642.5 (M^{+*}). Elemental analysis: Calculated for C₄₆H₅₈O₂: C, 85.93; H, 9.09; O, 4.98; Found: C, 71.27; H, 9.73.

Synthesis of 3,6-Dibromo-9,10-bis-(4-decyl-phenyl)-phenanthrene, 13. Compound 12 (2.5 g, 3.89 mmol) was used in the cyclisation procedure. Isolated yield=2.2 g (93%) as white needlelike crystals. ¹H NMR (CDCl₃, 300 MHz): δ 8.80 (d, J=8.1 Hz, 2H), 7.65 (d, J=8.1 Hz, 4H), 7.48 (d, J=8.2 Hz, 2H), 7.02 (s, 8H), 2.56 (t, J=7.8 Hz, 4H), 1.77-1.53 (m, 4H), 1.47-1.27 (m, 28H), 0.89 (t, J=6.9Hz, 6H). ¹³C NMR (CDCl₃, 300 MHz): 140.54, 137.14, 136.55, 131.86, 130.68, 129.72, 127.70, 127.27, 126.25, 125.98, 122.20, 35.40, 33.62, 31.74, 30.91, 29.48, 29.18, 28.60, 26.54, 22.50, 13.91. FDMS (m/z): 610.5 (M^{+*}). Elemental analysis: Calculated for C₄₆H₅₈: C, 90.43; H, 9.57; Found: C, 71.27; H, 9.73.

The bromination was performed by the procedure described above. Isolated yield=500 mg (41%) as white needlelike crystals. ¹H NMR (CDCl₃, 300 MHz): δ 8.81 (s, 2H), 7.59 (dd, J=8.8 and 1.8 Hz, 2H), 7.48 (d, J=8.8 Hz, 2H), 7.02 (dd, J=17.4 and 8.2 Hz, 8H), 2.55 (t, J=7.9 Hz, 4H), 1.61-1.51 (m, 4H), 1.37-1.21 (m, 28H), 0.93-0.83 (m, 6H). ¹³C NMR (CDCl₃, 300 MHz): 141.02, 137.23, 135.64, 130.85, 130.46, 130.14, 129.54, 127.46, 125.02, 120.84, 35.37, 31.74, 31.08, 29.47, 29.32, 29.18, 28.97, 22.50, 13.91. FDMS (m/z): 768.2 (M^{+*}). Elemental analysis: Calculated for C₄₆H₅₆Br₂: C, 71.87; H, 7.34; Br, 20.79; Found: C, 71.27; H, 9.73.

Synthesis of diboronic ester phenanthrene, 14. To a 100 mL Schlenk flask, dichlorophenanthrene 9 (1.7 g, 2.50 mmol), bis(pinacolato)diboron (1.89 g, 7.50 mmol), Pd₂(dba)₃ (0.2 g, 0.075 mmol), potassium acetate (0.858 g, 8.75 mmol), tricyclohexylphosphine (0.35 g, 1.25 mmol), and 25 mL of dry dioxane was added. The mixture was degassed by gently bubbling argon through 30 min at room temperature. The mixture was then heated at 110° C. under argon for 2 days. The cooled mixture was extracted with diethyl ether, washed with brine and then dried over MgSO₄. The crude product was chromatographed on silica gel using hexane as eluent and further purified by recrystallization from THF in ethanol. Isolated yield=500 mg (23%) as white needlelike crystals. ¹H NMR (CDCl₃, 300 MHz): δ 9.38 (s, 2H), 7.87 (dd, J=8.2 Hz, 2H), 7.61 (d, J=8.2 Hz, 2H), 7.00 (m, 8H), 2.56 (t, J=7.9 Hz, 4H), 1.60-1.53 (m, 4H), 1.47-1.39 (m, 24H), 1.35-1.25 (m, 28H), 0.93-0.85 (m, 6H). ¹³C NMR (CDCl₃, 300 MHz): 140.74, 138.50, 136.69, 133.98, 131.88, 130.83, 129.53, 127.45, 126.93, 35.59, 31.94, 31.29, 29.69, 29.54, 29.39, 29.16, 24.92, 22.70, 14.12. FDMS (m/z): 862.6 (M^{+*}). Elemental analysis: Calculated for C₅₈H₈₀B₂O₄: C, 80.73; H, 9.34; B, 2.51; 0, 7.42; Found: C, 71.27; H, 9.73.

Polymer of 3,6-LPAR Dibromide monomer 13 (89 mg, 0.12 mmol), monomer 14 (100 mg, 0.12 mmol), Aliquat® 336 (8 mg, 13.mol %), 1.5 mL of 2.0 M Na₂CO₃ and 4.0 mL of toluene were taken together in a schlenk flask and purged with argon for 15 minutes. To this, tetrakis(triphenylphosphine)palladium (5.8 mg g, 9.4 μmol) was added and the reaction mixture heated at 85° C. under vigorous stirring for 24 hours Phenylboronic acid was then added as an endcapper (2.0 mg), heated for 6 hours and then bromobenzene (5.0 mg) was added and heated again for an additional 6 hours. The reaction was poured into a mixture of methanol and 2.0 M HCl (1:1, 300 mL) and the precipitated product was redissolved in THF (10 mL) and added dropwise to methanol (200 mL). The resulting solid was filtered off and subjected to Soxhlet extraction for 24 h in acetone and filtered off and dried. Isolated yield of polymer 3,6-LPAP=110 mg (78%). GPC analysis Mₙ=5.33×10³ g/mol, M_{w}=6.82×10³ g/mol, and D=1.28 (against PPP standard); M_{w}=6.94×10³ g/mol, M_{w}=9.58×10³ g/mol, and D=1.38 (against PS standard). ¹H NMR (CDCl₃, 300 MHz): δ 9.25-9.07 (br m, 1H), 8.01-7.61 (br m, 4H), 7.11-6.39 (br m, 9H), 2.70-2.41 (br m, 4H), 1.77-1.41 (br m, 4H), 1.40-1.01 (br m, 28H), 0.97-0.78 (br m, 6H). Elemental analysis: Calculated for C₄₆H₅₆: C, 90.73; H, 9.27; Found: C, 71.27; H, 9.73.

Synthesis of (5-Bromo-2-iodo-phenyl)-(4-decyl-phenyl)-methanone, 15. The 5-Bromo-2-iodo-benzoyl chloride (4.0 g, 11.6 mmol) was used in Friedel-Crafts acylation and purified by 0-10% ethylacetate in hexane as eluent. Isolated yield=5.2 g (85%) as a yellow oil. ¹H NMR (CDCl₃, 300 MHz): δ 7.73 (dd, J=10.4 and 8.4 Hz, 3H), 7.40 (d, J=2.3 Hz, 1H), 7.32-7.28 (m, 3H), 2.66 (t, J=7.9 Hz, 2H), 1.69-1.58 (m, 2H), 1.37-1.21 (m, 14H), 0.87 (t, J=6.9 Hz, 3H). ¹³C NMR (CDCl₃, 300 MHz): 195.53, 150.51, 146.80, 141.32, 134.35, 132.99, 131.44, 130.99, 129.24, 122.75, 90.59, 36.52, 32.24, 31.35, 29.94, 29.79, 29.67, 23.03, 14.49. FDMS (m/z): 526.0 (M^{+*}). Elemental analysis: Calculated for C₂₃H₂₈BrIO: C, 52.39; H, 5.35; Br, 15.15; I, 24.07; O, 3.03; Found: C, 71.27; H, 9.73.

Synthesis of (4-Decyl-phenyl)-[4,4′-dibromo-2′-(4-decyl-benzoyl)-biphenyl-2-yl]-methanone, 16. Compound 15 (2.5 g, 4.70 mmol) was used in the Ullmann coupling and purified by 0-10% ethylacetate in hexane as eluent and further purified by recrystallization from hexane in ethanol. Isolated yield=1.1 g (58%) as a light yellow solid. ¹H NMR (CDCl₃, 300 MHz): δ 7.59 (d, J=8.2 Hz, 4H), 7.49 (m, 4H), 7.18 (d, J=8.2 Hz, 2H), 7.08 (d, J=8.2 Hz, 4H), 2.57 (t, J=7.9 Hz, 4H), 1.62-1.53 (m, 4H), 1.35-1.22 (m, 28H), 0.88 (t, J=6.9 Hz, 6H). ¹³C NMR (CDCl₃, 300 MHz): 195.31, 149.20, 140.12, 137.80, 134.13, 130.54, 128.27, 121.16, 36.05, 31.89, 31.05, 29.61, 29.46, 29.32, 22.67, 14.10. FDMS (m/z): 800.2 (M^{+*}). Elemental analysis: Calculated for C₄₆H₅₆Br₂O₂: C, 69.00; H, 7.05; Br, 19.96; O, 4.00; Found: C, 71.27; H, 9.73.

Synthesis of 2,7-Dibromo-9,10-bis-(4-decyl-phenyl)-phenanthrene, 17. Compound 16 (1.5 g, 1.87 mmol) was used in the cyclisation procedure. Isolated yield=1.1 g (76%) as white needlelike crystals. ¹H NMR (CDCl₃, 300 MHz): δ 8.58 (d, J=8.6 Hz, 2H), 7.75 (d, J=9.5 Hz, 4H), 6.99 (dd, J=20.8 and 8.1 Hz, 8H), 2.56 (t, J=7.9 Hz, 4H), 1.72-1.55 (m, 4H), 1.45-1.22 (m, 28H), 0.90 (t, J=6.5 Hz, 6H). ¹³C NMR (CDCl₃, 300 MHz): 141.10, 137.56, 135.33, 133.37, 130.44, 128.04, 127.54, 121.05, 33.61, 31.73, 30.91, 29.49, 29.18, 28.59, 26.54, 22.50, 13.91. FDMS (m/z): 768.3 (M^{+*}). Elemental analysis: Calculated for C₄₆H₅₆Br₂: C, 71.87; H, 7.34; Br, 20.79; Found: C, 71.27; H, 9.73.

Polymer of 2,7-PAR. The dichloride monomer 17 (368 mg, 0.60 mmol) was used in this polymerization and isolated yield of polymer 2,7-PAP=250 mg (68%). GPC analysis Mₙ=1.13×10⁴ g/mol, M_{w}=5.26×10⁴ g/mol, and D=4.66 (against PPP standard); Mₙ=1.48×10⁴ g/mol, M_{w}=1.07×10⁵ g/mol, and D=7.22 (against PS standard). ¹H NMR (CDCI₃, 300 MHz): δ 8.10-7.57 (br m, 2H), 6.99-6.11 (br m, 12H), 2.65-2.35 (br m, 4H), 1.88-1.21 (br m, 32H), 0.98-0.68 (br m, 6H). Elemental analysis: Calculated for C₄₆H₅₆: C, 90.73; H, 9.27; Found: C, 71.27; H, 9.73.

Synthesis of (5-Chloro-2-iodo-phenyl)-(4-decyl-phenyl)-methanone, 18. 5-Chloro-2-iodo-benzoyl chloride (3.0 g, 10.0 mmol) was used in Friedel-Crafts acylation and purified by 0-10% ethylacetate in hexane as eluent. Isolated yield=4.3 g (89%) as a yellow oil. ¹H NMR (CDCl₃, 300 MHz): δ 7.81 (d, J=8.4 Hz, 1H), 7.72 (d, J=8.3 Hz, 2H), 7.28 (d, J=7.7 Hz, 3H), 7.15 (dd, J=8.4 and 2.5 Hz, 1H), 2.66 (t, J=7.9 Hz, 2H), 1.73-1.61 (m, 2H), 1.45-1.22 (m, 14H), 0.90 (t, J=6.7 Hz, 3H). ¹³C NMR (CDCl₃, 300 MHz): 195.24, 150.07, 146.10, 140.67, 134.48, 132.58, 131.01, 130.55, 128.80, 128.23, 36.09, 31.82, 30.92, 29.52, 29.47, 29.37, 29.24, 29.21, 22.61, 14.06. FDMS (m/z): 482.0 (M^{+*}). Elemental analysis: Calculated for C₂₃H₂₈ClI: C, 57.21; H, 5.85; Cl, 7.34; I, 26.28; O, 3.31; Found: C, 71.27; H, 9.73.

Synthesis of (4-Decyl-phenyl)-[2-(4,4,5,5-tetramethyl-[1,3,2]dioxaborolan-2-yl)-phenyl]-methanone, 19. To a 100 mL Schlenk flask, (4-Decyl-phenyl)-(2-iodo-phenyl)-methanone (5.6 g, 12.5 mmol), bis(pinacolato)diboron (3.78 g, 13.7 mmol), palladium acetate (0.083 g, 0.37 mmol), potassium acetate (3.67 g, 37.5 mmol) and 25 mL of dry DMF were added. The mixture was degassed by gently bubbling argon through 30 min at room temperature. The mixture was then heated at 70□ under argon for overnight. The cooled mixture was extracted with diethyl ether, washed with brine and then dried over MgSO₄. The crude product was chromatographed on silica using 0-10% ethylacetate in hexane as eluent. Isolated yield=2.8 g (50%) as yellow oil. ¹H NMR (CDCl₃, 300 MHz): δ 7.70 (m, 4H), 7.47 (m, 3H), 7.22 (d, J=8.2 Hz, 3H), 2.64 (t, J=7.8 Hz, 2H), 1.69-1.55 (m, 2H), 1.43-1.23 (m, 14H), 1.20-1.55 (m, 12H), 0.87 (t, J=6.7 Hz, 3H). ¹³C NMR (CDCl₃, 300 MHz): 197.75, 148.04, 143.92, 135.69, 133.63, 130.12, 129.99, 129.56, 128.65, 128.17, 83.82, 35.91, 31.79, 31.18, 29.50, 29.48, 29.38, 29.22, 29.13, 24.92, 24.44, 22.58, 14.01. FDMS (m/z): 448.3 (M^{+*}). Elemental analysis: Calculated for C₂₉H₄₁BO₃: C, 77.67; H, 9.22; B, 2.41; O, 10.70; Found: C, 71.27; H, 9.73.

Synthesis of [4′-Chloro-2′-(4-decyl-benzoyl)-biphenyl-2-yl]-(4-decyl-phenyl)-methanone, 20. The boronate ester 19 (1.05 g, 2.34 mmol) and 18 (1.13 g, 2.34 mmol) were dissolved in THF (20 mL) in a 100 mL Schlenk flask. To this solution, 2 M K₂CO₃ aqueous solution (10 mL) was added and the solution purged with argon for 20 min, and then tetrakis(triphenylphosphine)palladium (81 mg, 0.07 mmol) was added and the reaction was heated with stirring at 85° C. The reaction was followed by TLC and after 2 days was worked up. The cooled mixture was extracted with diethyl ether, and the extract was washed with brine and then dried over MgSO₄. The crude product so obtained was purified by chromatography on silica using 0-10% ethylacetate in hexane as eluent. Isolated yield=1.3 g (82.0%) as a yellow oil. ¹H NMR (CDCl₃, 300 MHz): δ 7.71 (d, J=8.3 Hz, 1H), 7.62 (dd, J=8.3 and 4.0 Hz, 3H), 7.40-7.30 (m, 8H), 7.10-7.01 (m, 3H), 2.70-2.55 (m, 4H), 1.63-1.52 (m, 4H), 1.41-1.23 (m, 28H), 0.87 (t, J=6.7 Hz, 6H). ¹³C NMR (CDCI₃, 300 MHz): 196.91, 195.71, 150.18, 148.86, 148.63, 146.16, 140.73, 140.03, 138.94, 138.42, 134.84, 134.27, 132.82, 130.61, 128.12, 89.31, 25.99, 31.87, 31.07, 30.99, 29.59, 29.44, 29.30, 22.65, 14.08. FDMS (m/z): 676.4 (M^{+*}). Elemental analysis: Calculated for C₄₆H₅₇ClO₂: C, 81.56; H, 8.48; Cl, 5.23; O, 4.72; Found: C, 71.27; H, 9.73.

Synthesis of 2-Chloro-9,10-bis-(4-decyl-phenyl)-phenanthrene, 21. 20 (1.3 g, 1.92 mmol) was used in the cyclisation procedure. Isolated yield=1.1 g (89%) as white needlelike crystals. ¹H NMR (CDCl₃, 300 MHz): δ 8.71 (m, 2H), 7.60-7.51 (m, 5H), 7.01 (m, 8H), 2.55 (t, J=6.7 Hz, 4H), 1.67-1.55 (m, 4H), 1.41-1.23 (m, 28H), 0.89 (t, J=6.7 Hz, 6H). ¹³C NMR (CDCl₃, 300 MHz): 140.88, 138.46, 136.33, 136.18, 135.77, 133.10, 132.31, 130.59, 129.30, 128.11, 127.48, 127.33, 35.39, 33.61, 31.73, 30.91, 29.48, 26.54, 22.50, 13.91. FDMS (m/z): 644.4 (M^{+*}). Elemental analysis: Calculated for C₄₆H₅₇Cl: C, 85.60; H, 8.90; Cl, 5.49; Found: C, 71.27; H, 9.73.

Synthesis of 2-[9,10-Bis-(4-decyl-phenyl)-phenanthren-2-yl]-4,4,5,5-tetramethyl-[1,3,2]dioxaborolane, 22. To a 100 mL Schlenk flask, the chloride compound 21 (1.0 g, 1.55 mmol), bis-(pinacolato)diboron (0.51 g, 2.01 mmol), Pd₂(dba)₃ (0.042 g, 0.047 mmol), potassium acetate (0.23 g, 2.32 mmol), tricyclohexylphosphine (0.065 g, 0.23 mmol) and 25 mL of dry dioxane were added. The mixture was degassed by gently bubbling argon through 30 min at room temperature. The mixture was then heated at 110° C. under argon for 2 days. The cooled mixture was extracted with diethyl ether, washed with brine and then dried over MgSO₄. The crude product was chromatographed on silica with 0-5% ethylacetate in hexane as eluent. Isolated yield=0.82 g (72%) as yellow solid. ¹H NMR (CDCl₃, 300 MHz): δ 8.88 (dd, J=14.3 and 8.4 Hz, 2H), 8.12 (s, 1H), 8.03 (d, J=8.3 Hz, 1 H), 7.64 (m, 2H), 7.49 (m, 1 H), 7.02 (m, 8H), 2.57 (m, 4H), 1.77-1.55 (m, 4H), 1.40-1.21 (m, 40H), 0.89 (t, J=6.8 Hz, 6H). ¹³C NMR (CDCl₃, 300 MHz): 140.80, 140.66, 137.98, 137.41, 136.99, 136.68, 135.28, 132.67, 132.11, 131.37, 131.20, 131.08, 129.90, 128.61, 128.42, 127.57, 126.22, 83.61, 44.62, 33.95, 32.07, 31.25, 29.85, 25.14, 22.83, 14.24. FDMS (m/z): 736.5 (M^{+*}). Elemental analysis: Calculated for C₅₂H₆₉BO₂: C, 84,75; H, 9,44; B, 1,47; O, 4,34; Found: C, 71.27; H, 9.73.

Synthesis of 2,7-MT. The boronate ester 22 (0.5 g, 0.68 mmol) and 17 (0.24 g, 0.31 mmol) were dissolved in THF (20 mL) in a 100 mL Schlenk flask. To this solution, 2 M K₂CO₃ aqueous solution (10 mL) was added and the solution was purged with argon for 20 min, and then tetrakis(triphenylphosphine)palladium (21 mg, 18 μmol) was added and the reaction mixture heated with stirring at 85° C. The reaction was followed by TLC and after 48 h, the mixture was cooled, extracted with diethyl ether, and the extract was washed with brine and then dried over MgSO₄. The crude product so obtained was purified by chromatography on silica with 0-25% dichloromethane in hexane as eluent. Isolated yield=150 mg (26%) as a light yellow solid. ¹H NMR (CDCl₃, 500 MHz): δ 8.78 (m, 6H), 7.84 (m, 8H), 7.63 (d, J=7.8 Hz, 4H), 7.47 (t, J=7.1 Hz, 2H), 7.01 (d, J=11.9 Hz, 24H), 2.69-2.51 (m, 12H), 1.71-1.55 (m, 12H), 1.37-1.21 (m, 84H), 0.95-0.81 (m, 18H). 13C NMR (CDCl₃, 500 MHz): 140.82, 140.66, 139.30, 138.04, 137.87, 137.61, 136.90, 136.64, 132.51, 132.23, 130.98, 129.91, 129.15, 128.99, 127.99, 127.56, 126.54, 126.27, 125.70, 123.05, 122.48, 35.71, 35.66, 31.96, 31.33, 29.73, 29.62, 29.55, 29.38, 29.26, 22.68, 14.05. FDMS (m/z): 1829.1 (M^{+*}). Elemental analysis: Calculated for C₁₃₈H₁₇₀: C, 90.63; H, 9.37; Found: C, 71.27; H, 9.73.

Synthesis of 3-Bromo-9,10-bis-(4-decyl-phenyl)-phenanthrene, 23. 9,10-Bis-(4-decyl-phenyl)-phenanthrene (1.0 mg, 1.63 mmol) with catalytic amount of iodine was dissolved in CCl₄ (10 mL). To this mixture, bromine (0.26 g, 1.63 mmol) was added dropwise at 0° C. The reaction mixture was slowly allowed to warm to room temperature overnight. A further bromine (0.13 g, 0.82 mmol) portion was then added with stirring and monitored by FDMS, which showed nearly quantitative formation of the monobromide after 12 h. The reaction was quenched by addition of aqueous Na₂S₂O₅ solution and then extracted into DCM, washed with brine and dried. The crude product was chromatographed on silica gel using hexane as eluent and further purified by recrystallization from THF in ethanol. Isolated yield=250 mg (20%) as a white needlelike crystal. ¹H NMR (CDCl₃, 300 MHz): δ 8.91 (s, 1 H), 8.70 (d, J=8.3 Hz, 1H), 7.65 (dd, J=13.4 and 6.9 Hz, 2H), 7.51 (m, 3H), 7.20-7.00 (m, 8H), 2.65-2.51 (m, 4H), 1.77-1.45 (m, 4H), 1.41-1.25 (m, 28H), 0.89 (t, J=6.7 Hz, 6H). ¹³C NMR (CDCl₃, 300 MHz): 140.53, 137.136.53, 135.96, 135.79, 131.98, 131.06, 130.38, 128.44, 137.12, 120.30, 35.17, 31.52, 30.88, 29.26, 29.11, 28.96, 28.75, 22.28, 13.69. FDMS (m/z): 689.1 (M^{+*}). Elemental analysis: Calculated for C₄₆H₅₇Br: C, 80.09; H, 8.33; Br, 11.58; Found: C, 71.27; H, 9.73

Synthesis of 3,6-MT. The boronate ester 23 (100 mg, 0.116 mmol) and compound 14 (0.18 g, 0.255 mmol) were dissolved in THF (10 mL) in a 100 mL Schlenk flask. To this solution,2 M K₂CO₃ aqueous solution (5 mL) was added and the solution was purged with argon for 20 min, and then tetrakis(triphenylphosphine)palladium (6.7 mg, 5.80 μmol) was added and the reaction mixture heated with stirring at 85° C. The reaction was followed by TLC and after 48 h, the mixture was cooled, extracted with diethyl ether, and the extracts washed with brine and then dried over MgSO₄. The crude product so obtained was purified by chromatography on silica with 0-25% dichloromethane in hexane as eluent. Isolated yield=150 mg (71%) as white solid.

¹H NMR (CDCl₃, 300 MHz): δ 9.28 (s, 2H), 9.18 (s, 2H), 8.94 (d, J=8.3 Hz, 2H), 7.96 (t, J=7.1 Hz, 4H), 7.85-7.71 (m, 4H), 7.66 (t, J=7.8 Hz, 4H), 7.50 (m, 2H), 7.29-7.10 (m, 24H), 2.58 (m, 12H), 1.70-1.52 (m, 12H), 1.42-1.27 (m, 84H), 0.93-0.82 (m, 18H). ¹³C NMR (CDCl₃, 300 MHz): 140.74, 139.26, 139.04, 137.35, 137.18, 136.98, 136.51, 132.21, 131.48, 131.15, 130.71, 130.25, 130.12, 129.83, 127.41, 126.09, 122.34, 121.22, 23.42, 31.75, 31.14, 29.49, 29.35, 29.26, 29.19, 29.10, 22.51, 13.92. FDMS (m/z): 1828.0 (M^{+*}). Elemental analysis: Calculated for C₁₃₈H₁₇₀: C, 90.63; H, 9.37; Found: C, 71.27; H, 9.73.

What is claimed is:

1. An organic electronic device comprising at least one charge transport layer or a photoactive layer comprising a polymer having formula I or Formula II 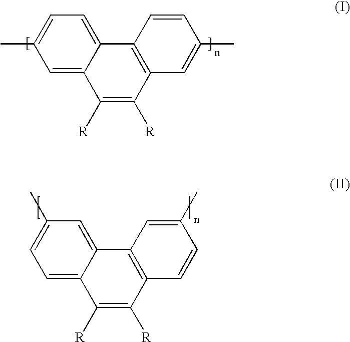
wherein:
R is the same or different at each occurrence and is H, alkyl, or aryl, and
n is greater than 5, wherein if the above polymer is used in the photoactive layer it is acting as a host or receiving layer for a photoactive dopant such as an organic small molecule or an organicmetallic compound.

2. The device of claim 1, wherein R is a decly group.

3. The device of claim 1, wherein R is a phenyldecyl group.

4. The device of claim 1, wherein the layer is a hole transport layer.

5. The device of claim 1, where in the device further has a buffer layer over the anode.

6. The device of claim 1, wherein the device further comprises the use of the polymer of claim 1 as hole transport layer and as a host for at least one light emitting layer comprising a small molecule or organic metallic compound.
